(19) United States
(12) Patent Application Publication
(10) Pub. No.: US 2025/0124621 A1
(43) Pub. Date: Apr. 17, 2025

(54) DISPLAY DEVICE, RECORDING MEDIUM, AND DISPLAY METHOD

(71) Applicant: Tokyo Electron Limited, Tokyo (JP)

(72) Inventors: Masahide Tadokoro, Sapporo City (JP); Tetsuya Sakazaki, Koshi City (JP)

(21) Appl. No.: 18/909,227

(22) Filed: Oct. 8, 2024

(30) Foreign Application Priority Data
Oct. 12, 2023 (JP) 2023-176992
Jul. 25, 2024 (JP) 2024-119535

(51) Int. Cl. G06T 11/20; G06T 7/00; G06T 7/73; H01L 21/67

(52) U.S. Cl. CPC G06T 11/206; G06T 7/0004; G06T 7/73; G06T 2207/30148; H01L 21/67288

(57) ABSTRACT

A display method includes acquiring, based on an image obtained by imaging a peripheral region of a front surface of a substrate having a film formed on the front surface thereof, edge information indicating a relationship between a circumferential position and an edge position of the film in a radial direction of the substrate for each of multiple circumferential positions around a center of the substrate; displaying, on a monitor, a graph indicating the edge position for each of the multiple circumferential positions based on the edge information; and determining, before displaying the graph on the monitor, a display range for the edge position on the graph based on statistical information of the edge position included in the edge information.

### CROSS-REFERENCE TO RELATED APPLICATION

This application claims the benefit of Japanese Patent Application Nos. 2023-176992 and 2024-119535 filed on Oct. 12, 2023 and Jul. 25, 2024, respectively, the entire disclosures of which are incorporated herein by reference.

### TECHNICAL FIELD

The various aspects and embodiments described herein pertain generally to a display device, a recording medium, and a display method.

### BACKGROUND

Patent Document 1 discloses a coating method including a process of removing a coating film on a peripheral portion of a substrate.
Patent Document 1: Japanese Patent Laid-open Publication No. 2006-086189

### SUMMARY

In an exemplary embodiment, a display method includes acquiring, based on an image obtained by imaging a peripheral region of a front surface of a substrate having a film formed on the front surface thereof, edge information indicating a relationship between a circumferential position and an edge position of the film in a radial direction of the substrate for each of multiple circumferential positions around a center of the substrate; displaying, on a monitor, a graph indicating the edge position for each of the multiple circumferential positions based on the edge information; and determining, before displaying the graph on the monitor, a display range for the edge position on the graph based on statistical information of the edge position included in the edge information.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view schematically illustrating an example of a substrate processing apparatus;

FIG. 2 is a front view schematically illustrating the example of the substrate processing apparatus;

FIG. 3 is a schematic diagram illustrating an example of a liquid processing device;

FIG. 4 is a schematic diagram illustrating an example of an inspection apparatus;

FIG. 5 is a block diagram illustrating an example of a functional configuration of a control device and a display device;

FIG. 6A to FIG. 6D are schematic diagrams illustrating a processing performed by the liquid processing device;

FIG. 7A is a schematic diagram illustrating an example of a captured peripheral image and FIG. 7B is a diagram illustrating an example of edge information;

FIG. 8 is a schematic diagram illustrating an example of a monitor with a graph displayed thereon;

FIG. 9 is a diagram showing an example of a relationship between a display range and statistical information;

FIG. 10 is a block diagram illustrating an example of a hardware configuration of the control device and the display device;

FIG. 11 is a flowchart illustrating an example of a display method;

FIG. 12 is a schematic diagram illustrating an example of the monitor with a graph displayed thereon;

FIG. 13A and FIG. 13B present an example of graphs acquired before and after adjustment;

FIG. 14A and FIG. 14B present an example of graphs acquired during an examination process;

FIG. 15A and FIG. 15B present an example of graphs acquired during an examination process;

FIG. 16 is a schematic diagram illustrating an example of the monitor with a graph displayed thereon;

FIG. 17 is a schematic diagram illustrating an example of the monitor with a graph and related information displayed thereon;

FIG. 18 is a diagram showing an example of a relationship between abnormality categories, abnormality factors, and candidates for countermeasure;

FIG. 19A and FIG. 19B are schematic diagrams illustrating an example of a bevel portion formed at an outer periphery of a substrate, and FIG. 19C is a schematic diagram illustrating a state of the substrate with a plurality of films formed thereon;

FIG. 20 is a schematic diagram illustrating an example of the monitor with a graph displayed thereon;

FIG. 21 is a schematic diagram illustrating an example of the monitor with a graph and related information displayed thereon;

FIG. 22A to FIG. 22D are diagrams for describing examples of contribution rates for respective non-uniformity components; and

FIG. 23 is a schematic diagram illustrating an example of the monitor with a graph displayed thereon.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, a wafer processing system as a substrate processing apparatus according to an exemplary embodiment will be described with reference to the accompanying drawings. In the present specification, parts having substantially the same functions and configurations will be assigned the same reference numerals, and redundant description thereof will be omitted.

### <Wafer Processing System>

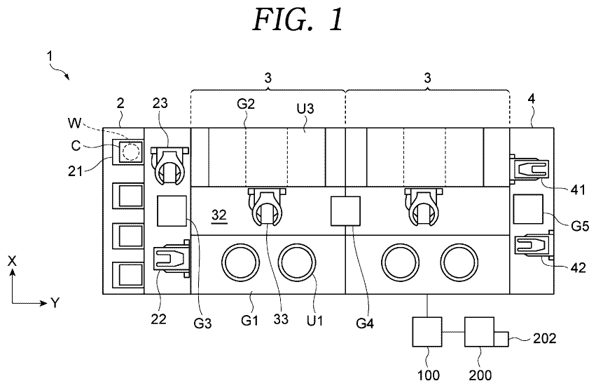

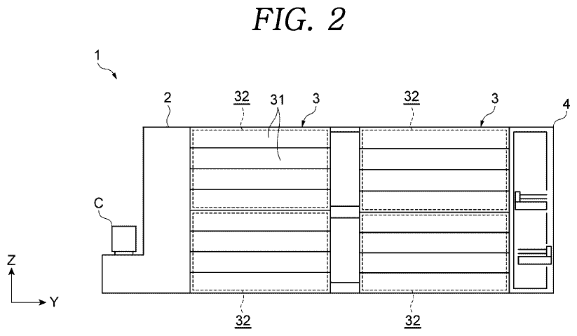

First, a configuration of a wafer processing system according to the present exemplary embodiment will be described. FIG. 1 and FIG. 2 are a plan view and a front view, respectively, schematically illustrating a configuration of a wafer processing system 1. In the present exemplary embodiment, the wafer processing system 1 will be described as a photolithography processing system configured to perform a processing of forming a resist film on a wafer W and a processing of developing the resist film. The wafer W, which is a processing target to be processed by the wafer processing system 1, may be of a circular shape.

The wafer processing system 1 includes, as shown in FIG. 1, a cassette station 2 into/out of which a cassette C accommodating a plurality of wafers W is transferred, and a processing station 3 equipped with a plurality of various processing apparatuses configured to perform predetermined processes on the wafer W. The wafer processing system 1 has a configuration in which the cassette station 2, the processing station 3, and an interface station 4 configured to deliver the wafer W to/from an exposure apparatus (not shown) adjacent to the interface station 4 on the opposite side to the processing station 3 are integrally connected. Further, as shown in FIG. 1, two processing stations 3 are provided between the cassette station 2 and the interface station 4. However, one processing station 3 or three or more processing stations 3 may be provided.

The cassette station 2 is equipped with a plurality of cassette placing tables 21 and wafer transfer devices 22 and 23. In the cassette station 2, the wafer transfer device 22 or 23 is configured to transfer the wafer W between the cassette C placed on the cassette placing table 21 and the processing station 3. For this reason, each of the wafer transfer devices 22 and 23 is equipped with a driving mechanism movable in an X-axis direction, a Y-axis direction and a vertical direction and around a vertical axis (in a θ-direction) as necessary, or may be equipped with a driving mechanism movable in all directions.

At least one of the wafer transfer devices 22 and 23 can deliver the wafer W to/from the cassette C, and can also perform a delivery operation of the wafer W with respect to the processing station 3. The delivery operation of the wafer W with respect to the processing station 3 refers to, for example, delivery of the wafer W with respect to a third block G3 equipped with a transit apparatus that can be accessed by a wafer transfer device 33, which will be described later, within the processing station 3. The third block G3 may be equipped with a plurality of transit apparatuses (not shown) arranged in the vertical direction.

Also, the cassette station 2 may be equipped with an inspection apparatus (not shown) configured to perform inspection on the wafer W at a position accessible by any one of the wafer transfer devices 22 and 23.

The processing station 3 is provided with a plurality of blocks, for example, three blocks including first, second and fourth blocks G1, G2 and G4. Also, as shown in FIG. 2, a plurality of layers 31 including the first and second blocks G1 and G2 is stacked in the vertical direction. For example, the first block G1 is provided at a front surface side of the processing station 3 (in the negative X-axis direction in FIG. 1) and the second block G2 is provided at a rear surface side of the processing station 3 (in the positive X-axis direction in FIG. 1). The fourth block G4 is provided at the side of the interface station 4 of the processing station 3 (in the positive Y-axis direction in FIG. 1) or at a connection portion with another adjacent processing station 3. The fourth block G4 may be equipped with a plurality of transit apparatuses arranged in the vertical direction. Also, the above-described third block G3 may be provided within the processing station 3.

In the first block G1, a plurality of processing apparatuses, such as a patterning film forming apparatus and a developing apparatus all of which are not illustrated, is arranged. The patterning film forming apparatus may include, for example, a resist film forming apparatus and an anti-reflection film forming apparatus. For example, the plurality of processing apparatuses is arranged in a horizontal direction. Also, the numbers, arrangement and types of these apparatuses can be selected as required.

For example, in the patterning film forming apparatus and the developing apparatus, a predetermined processing liquid or a predetermined gas is supplied onto the wafer W. Accordingly, in the patterning film forming apparatus, a resist film as a mask for forming a pattern of a film on a lower layer side is formed or an anti-reflection film for efficiently performing a light radiation processing, such as an exposure processing, is formed. Further, in the developing apparatus, the mask is formed into a concave and convex shape by removing a part of the exposed resist film. The first block G1 may be provided with a liquid processing device U1 as an example of the patterning film forming apparatus.

For example, in the second block G2, thermal treatment apparatuses (not shown) configured to perform thermal treatments, such as heating and cooling, on the wafer W are arranged and provided in the vertical direction and in the horizontal direction. Further, although not shown, in the second block G2, a hydrophobizing apparatus configured to perform hydrophobization for enhancing fixedness between a resist liquid and the wafer W and an edge exposure apparatus configured to expose an outer peripheral portion of the wafer W are arranged and provided in the vertical direction (in the Z-axis direction in FIG. 2) and in the horizontal direction. The numbers and arrangement of the thermal treatment apparatuses, the hydrophobizing apparatus and the edge exposure apparatus can be selected as required.

As shown in FIG. 1, when viewed from the top, a wafer transfer region 32 is formed between the first block G1 and the second block G2. For example, a wafer transfer device 33 is provided in the wafer transfer region 32.

The wafer transfer device 33 has a transfer arm configured to be movable in the X-axis direction, the Y-axis direction, the θ-direction, and the vertical direction, for example. The wafer transfer device 33 moves within the wafer transfer region 32 to transfer the wafer W to a predetermined apparatus within the first block G1, the second block G2, the third block G3, and the fourth block G4 around the wafer transfer device 33. As shown in FIG. 1, the processing station 3 is plural in number. In this case, the wafer transfer device 33 provided in the processing station 3 located at the side of the interface station 4 can transfer the wafer W to a predetermined apparatus within a fifth block G5, which will be described later, in addition to the first, second and fourth blocks G1, G2 and G4.

For example, a plurality of wafer transfer devices 33 is provided in the vertical direction. One of the wafer transfer devices 33 can transfer the wafer W to a predetermined apparatus located at a height position corresponding to the layers 31 on the upper side among the plurality of layers 31 stacked in the vertical direction (see FIG. 2). Also, another wafer transfer device 33 can transfer the wafer W to a predetermined apparatus located at a height position corresponding to the layers 31 located under the layers 31 on the upper side. A plurality of wafer transfer regions 32 is provided to enable the above-described transfer of the wafer W. Further, the wafer transfer device 33 may be provided for each layer 31. As such, the number of the wafer transfer devices 33 and the number of the layers 31 corresponding to each wafer transfer device 33 can be selected as required.

In the wafer transfer region 32, the first block G1 or the second block G2, a shuttle transfer apparatus (not shown) may be provided. The shuttle transfer apparatus is configured to linearly transfer the wafer W between a space adjacent to one side of the processing station 3 and another space adjacent to the other side.

The interface station 4 is provided with the fifth block G5 equipped with a plurality of transit apparatuses, and wafer transfer devices 41 and 42. In the interface station 4, the wafer transfer device 41 or 42 is configured to transfer the wafer W between the fifth block G5 to and from which the wafer W is delivered by the wafer transfer device 33 and the exposure apparatus. For this reason, each of the wafer transfer devices 41 and 42 is equipped with a driving mechanism movable in the X-axis direction, the Y-axis direction and the vertical direction and about the vertical axis (in the θ-direction) as necessary, or may be equipped with a driving mechanism movable in all directions. At least one of the wafer transfer devices 41 and 42 can support and transfer the wafer W between the transit apparatus within the fifth block G5 and the exposure apparatus.

A cleaning apparatus configured to clean a front surface of the wafer W and the above-described edge exposure apparatus may be provided at a position accessible by any one of the wafer transfer devices 41 and 42 within the interface station 4.

The inspection apparatus may be provided in the cassette station 2 as described above. Alternatively, the processing station 3 and the interface station 4 may be provided with the inspection apparatus at a position accessible by any one of the transfer arms (33, 41 and 42 in FIG. 1 or FIG. 2) in the processing station 3 and the interface station 4. As an example of the inspection apparatus, an inspection device U3 may be provided in the processing station 3.

The wafer processing system 1 is provided with a control device 100. The control device 100 is, for example, a computer and has a program storage (not shown). The program storage stores a program for controlling the processes on the wafer W in the wafer processing system 1. Also, the program storage stores a program for executing the processes on the wafer W in the wafer processing system 1 by controlling the operations of a driving system, such as the above-described various processing apparatuses and transfer devices. The above-described programs are recorded on a computer-readable recording medium H, and may be installed into the control device 100 from the recording medium H.

The wafer processing system 1 may be equipped with a display device 200 in addition to the control device 100. The display device 200 is communicatively connected to the control device 100. Details of the display device 200 will be discussed later.

### <Operation of Wafer Processing System>

The wafer processing system 1 is configured as described above. Hereinafter, an example of a wafer processing performed by the wafer processing system 1 configured as described above will be described.

First, the cassette C accommodating the wafers W is carried into the cassette station 2 of the wafer processing system 1 to be placed on the cassette placing table 21. Then, each of the wafers W in the cassette C is successively taken out by the wafer transfer device 22 or 23 and transferred to the transit apparatus in the third block G3.

The wafer W transferred to the transit apparatus in the third block G3 is supported and transferred by the wafer transfer device 33 to the hydrophobizing apparatus in the second block G2, and subjected to hydrophobization. Then, the wafer W is transferred by the wafer transfer device 33 to the resist film forming apparatus (for example, the liquid processing device U1), and a resist film is formed on the wafer W. Thereafter, the wafer W is transferred to the thermal treatment apparatus and subjected to pre-baking. The pre-baked wafer W is transferred to the transit apparatus in the fifth block G5. If the processing station 3 is plural in number as shown in FIG. 1 and FIG. 2, the wafer W may be placed on the transit apparatus in the fourth block G4 before being transferred to the transit apparatus in the fifth block G5, and then delivered to and from the plurality of wafer transfer devices 33. Also, when necessary, the wafer W may be transferred by the wafer transfer device 33 to the edge exposure apparatus, and a peripheral portion of the wafer W may be exposed.

The wafer W transferred to the transit apparatus in the fifth block G5 is transferred by the wafer transfer devices 41 and 42 to the exposure apparatus and exposed into a predetermined pattern. Before this exposure process, the wafer W may be cleaned by the cleaning apparatus.

The exposed wafer W is transferred by the wafer transfer devices 41 and 42 to the transit apparatus in the fifth block G5. Then, the wafer W is transferred by the wafer transfer device 33 to the thermal treatment apparatus and subjected to post-exposure baking.

The post-exposure baked wafer W is transferred by the wafer transfer device 33 to the developing apparatus and subjected to a development processing. After the development processing, the wafer W is transferred by the wafer transfer device 33 to a thermal treatment apparatus 40 and subjected to post-baking.

Thereafter, the wafer W is transferred by the wafer transfer device 33 to the transit apparatus in the third block G3 and then transferred by the wafer transfer device 22 or 23 of the cassette station 2 to a predetermined cassette C of the cassette placing table 21. Thus, the series of photolithography processes are ended. During the series of photolithography processes, inspection of the wafer W may be performed by using the inspection device U3. In an adjustment process before starting the processing of the wafer W through the series of photolithography processes, inspection of an adjustment wafer W may be performed by using the inspection device U3.

The wafer processing system of the present disclosure is not limited to the above-described configuration and operation. For example, it has been described in the above-described exemplary embodiment that the wafer W is delivered between the interface station 4 and the exposure apparatus. However, the wafer processing system may not be directly connected to the exposure apparatus. In this case, for example, the wafer W may be transferred from the cassette station 2 to the processing station 3 and subjected to a necessary processing, and then may be returned to the cassette station 2 so as to be transferred to the outside. Also, an unnecessary one of the exemplified processing apparatuses may not be provided or may not perform a corresponding processing.

### <Liquid Processing Device>

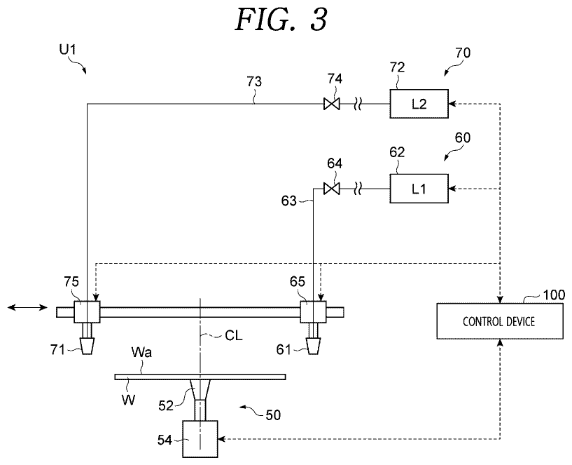

Subsequently, referring to FIG. 3, an example of the liquid processing device U1 will be described. The liquid processing device U1 is configured to supply a processing liquid for forming a resist film (hereinafter referred to as “processing liquid L1”) to a front surface Wa of the wafer W to form a film of the processing liquid L1 (hereinafter referred to as “resist film”). The liquid processing device U1 is also configured to supply a processing liquid for removing the resist film (hereinafter referred to as “processing liquid L2”) to a peripheral portion of the resist film to acquire the resist film whose peripheral portion is removed. The liquid processing device U1 has, by way of example, a rotating holder 50, a first processing liquid supply 60, and a second processing liquid supply 70.

The rotating holder 50 is configured to hold and rotate the wafer W. By way of example, the rotating holder 50 has a holder 52 and a rotational driver 54. The holder 22 supports a central portion of the wafer W, which is horizontally placed thereon with the front surface Wa facing upwards, and holds the wafer W by attraction (for example, vacuum attraction). The rotational driver 54 includes a power source such as, but not limited to, an electric motor, and is configured to rotate the holder 52 around a vertical central axis CL. As a result, the wafer W held by the holder 52 is rotated. The holder 52 may hold the wafer W such that the central axis CL coincides with a center of the wafer W.

The first processing liquid supply 60 is configured to supply the processing liquid L1 to the front surface Wa of the wafer W. The first processing liquid supply 60 has a nozzle 61, a liquid source 62, a supply path 63, a valve 64, and a nozzle driver 65. The nozzle 61 discharges the processing liquid L1 toward the front surface Wa of the wafer W held by the holder 52. The liquid source 62 stores the processing liquid L1 therein, and force-feeds the processing liquid L1 to the nozzle 61. The supply path 63 connects the liquid source 62 to the nozzle 61, and guides the processing liquid L1 from the liquid source 62 to the nozzle 61. The valve 64 is, for example, an air-operated valve, and serves to open or close a flow path in the supply path 63. The nozzle driver 65 includes a power source such as an electric motor, and moves the nozzle 61 in a horizontal direction. The nozzle driver 65 moves the nozzle 61 between, for example, the central axis CL and an area outside the wafer W. The valve 64 and the nozzle driver 65 are operated based on an operation instruction from the control device 100.

The second processing liquid supply 70 is configured to supply the processing liquid L2, which is a chemical liquid for removing the resist film, to the front surface Wa of the wafer W. The processing liquid L2 is a solvent capable of removing (dissolving) the resist film formed by the processing liquid L1. As a specific example, the processing liquid L2 may be an organic solvent such as thinner. The second processing liquid supply 70 has, for example, a nozzle 71, a liquid source 72, a supply path 73, a valve 74, and a nozzle driver 75.

The nozzle 71 discharges the processing liquid L2 toward the front surface Wa of the wafer W held by the holder 52. The liquid source 72 stores the processing liquid L2 therein, and force-feeds the processing liquid L2 to the nozzle 71. The supply path 73 connects the liquid source 72 to the nozzle 71, and guides the processing liquid L2 from the liquid source 72 to the nozzle 71. The valve 74 is, for example, an air-operated valve, and serves to open or close a flow path in the supply path 73. The nozzle driver 75 includes a power source such as an electric motor, and moves the nozzle 71 in the horizontal direction. The valve 74 and the nozzle driver 75 are operated based on an operation instruction from the control device 100. With the nozzle 71 located by the nozzle driver 75 at a position where it is capable of discharging the processing liquid L2 onto a peripheral region of the front surface Wa, the processing liquid L2 is discharged from the nozzle 71 while the wafer W is being rotated by the rotating holder 50, so that the peripheral portion of the resist film is removed.

### (Inspection Device)

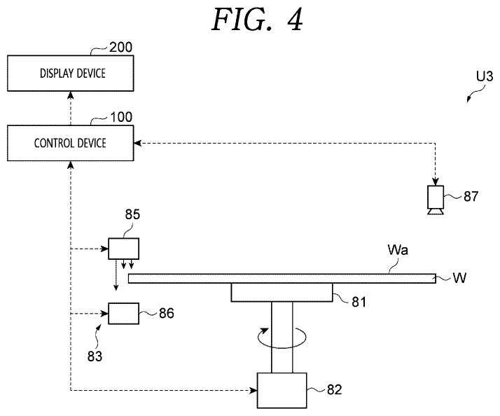

Now, referring to FIG. 4, an example configuration of the inspection device U3 will be explained in detail. The inspection device U3 images the front surface Wa of the wafer W to obtain image data as surface information indicating the state of the front surface Wa. Also, the inspection device U3 adjusts the direction of the wafer W by using an index portion such as a notch formed on the wafer W. As shown in FIG. 4, the inspection device U3 has a holder 81, a rotational driver 82, a detector 83, and an imaging device 87.

The holder 81 supports the central portion of the wafer W, which is horizontally placed thereon with the front surface Wa facing upwards, and holds the wafer W by attraction (for example, vacuum attraction). The rotational driver 82 includes a power source such as an electric motor, and rotates the holder 81 around a vertical central axis. Accordingly, the wafer W held by the holder 81 is rotated.

The detector 83 detects the index portion of the wafer W. The detector 83 has, for example, a light emitter 85 and a light receiver 86. The light emitter 85 emits light toward the peripheral portion of the wafer W being rotated. For example, the light emitter 85 is disposed above the peripheral portion of the wafer W, and emits the light downwards. The light receiver 86 receives the light emitted by the light emitter 85. For example, the light receiver 86 is disposed below the peripheral portion of the wafer W so as to face the light emitter 85. The light receiver 86 outputs light reception information indicating the result of receiving the light to the control device 100. Based on the light reception information, the index portion is adjusted to a predetermined angle by the control device 100. That is, the direction of the wafer W is adjusted.

The imaging device 87 is a camera configured to image at least the peripheral region of the front surface Wa of the wafer W. When the resist film free of its peripheral portion is formed on the front surface Wa of the wafer W, the inspection device U3 images an imaging range including an edge of the resist film and an edge of the wafer W with the imaging device 87, while rotating the holder 81 (wafer W) with the rotational deriver 82. The imaging device 87 is disposed above the wafer W held by the holder 81. The imaging device 87 is operated in response to an operation instruction from the control device 100, and outputs the acquired image data to the control device 100. Based on this image data, the state of the peripheral portion of the front surface Wa (resist film) is inspected.

### (Control Device)

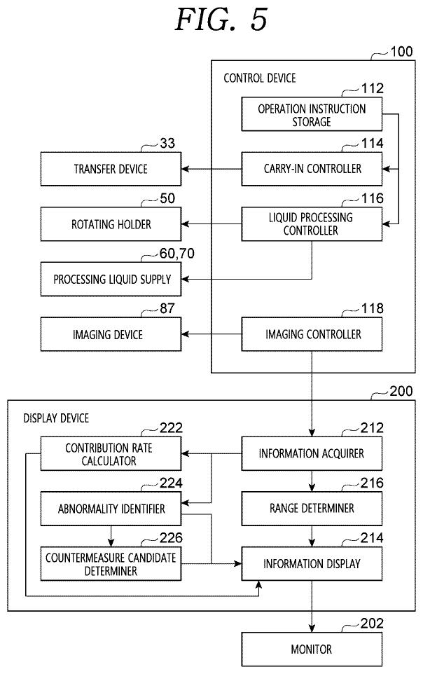

Now, an example of the control device 100 will be described. The control device 100 is configured to control the respective apparatuses and devices included in the wafer processing system 1. As shown in FIG. 5, the control device 100 includes, as its functional components (hereinafter referred to as “functional blocks”), an operation instruction storage 112, a carry-in controller 114, a liquid processing controller 116, and an imaging controller 118. A processing performed by these functional blocks corresponds to a processing performed by the control device 100.

The operation instruction storage 112 stores operation conditions for the formation of the resist film and the removal of the peripheral portion of the resist film by the liquid processing device U1. These operation conditions may be adjustable by an operator such as a worker. The operation conditions include, by way of example, a position of the transfer device when transferring the wafer W to the rotating holder 50 so that the wafer W is held thereon, and a position of the nozzle 71 when removing the peripheral portion of the resist film.

The carry-in controller 114 controls the wafer transfer device 33 to place the wafer W before being subjected to the formation of the resist film on the holder 52 of the rotating holder 50. The carry-in controller 114 may control the wafer transfer device 33 to carry the wafer W into the liquid processing device U1 and place the wafer W on the holder 52 based on the operation conditions stored in the operation instruction storage 112. At this time, the carry-in controller 114 may control the wafer transfer device 33 to move to a position, which is indicated by the operation condition, where it is supposed to deliver the wafer W.

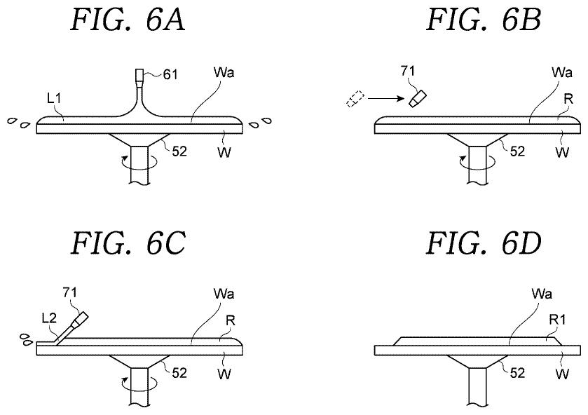

The liquid processing controller 116 controls the liquid processing device U1 to form the resist film on the front surface Wa of the wafer W. For example, the liquid processing controller 116 controls the nozzle driver 65 to place the nozzle 61 on the central axis CL in the state that the wafer W is held by the holder 52. Then, as shown in FIG. 6A, the liquid processing controller 116 controls the first processing liquid supply 60 to discharge the processing liquid L1 from the nozzle 61 while rotating the holder 52 by the rotational driver 54.

The liquid processing controller 116 controls the liquid processing device U1 to remove the peripheral portion of the resist film after the resist film is formed. By way of example, the liquid processing controller 116 controls the nozzle driver 75 to place the nozzle 71 based on the operation condition stored in the operation instruction storage 112. FIG. 6B illustrates an example of positioning the nozzle 71. In FIG. 6B and so forth, the resist film formed by the processing liquid L1 is denoted by “R”. The liquid processing controller 116 may control the nozzle driver 75 to place the nozzle 71 at a position indicated by the aforementioned operation conditions.

After the nozzle 71 is positioned, the liquid processing controller 116 controls the second processing liquid supply 70 to discharge the processing liquid L2 configured to remove the resist film R from the nozzle 71 onto a peripheral portion of the resist film R while rotating the holder 52 by the rotational driver 54. FIG. 6C illustrates an example of discharging the processing liquid L2 from the nozzle 71. By discharging the processing liquid L2 from the nozzle 71 onto the peripheral portion of the resist film R while rotating the wafer W, the resist film R whose peripheral portion is removed is obtained, as shown in FIG. 6D. In removing the peripheral portion of the resist film R, the peripheral portion may be removed along the entire circumference of the resist film R. In this case, a portion of the resist film R located in an annular region near an edge of the resist film R is removed. Hereinafter, the resist film R with its peripheral portion removed will be simply referred to as “resist film R1”.

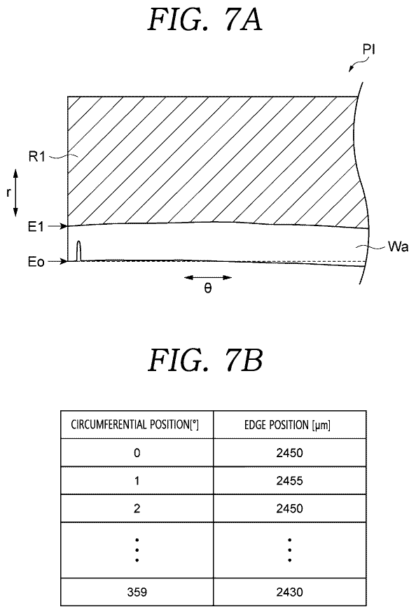

The imaging controller 118 controls the inspection device U3 to have the imaging device 87 image the peripheral region of the front surface Wa of the wafer W on which the resist film R1 is formed. The imaging controller 118 acquires image data from the imaging device 87 by controlling the imaging device 87 to capture an imaging range including the edge of the resist film R1 and the edge of the wafer W, while rotating the holder 81 holding the wafer W thereon by the rotational driver 82. FIG. 7A is an example schematic diagram of an image (an image based on the aforementioned image data) obtained by imaging the peripheral portion of the front surface Wa. In the image illustrated in FIG. 7A, a horizontal direction represents a circumferential direction around the center of the wafer W, and a vertical direction represents a radial direction of the wafer W.

### (Display Device)

Now, an example of the display device 200 will be described. The display device 200 is a device configured to display a part of the information acquired by the control device 100 to the operator or the like. A monitor 202 is connected to the display device 200 (see FIG. 1), and the display device 200 displays the state acquired from the control device 100 on the monitor 202. For example, the operator or the like checks the information displayed on the monitor 202 by the display device 200 and adjusts the operation conditions stored in the operation instruction storage 112. For example, the display device 200 has, as functional blocks, an information acquirer 212, an information display 214, and a range determiner 216. A processing performed by these functional blocks corresponds to a processing performed by the display device 200.

The information acquirer 212 acquires edge information based on an image (hereinafter referred to as a “captured peripheral image PI”) obtained by imaging the peripheral region on the front surface Wa of the wafer W on which the resist film R1 (coating) is formed. The edge information indicates a relationship between each circumferential position included in multiple circumferential positions around the center of the wafer W and an edge position of the resist film R1 in the radial direction of the wafer W. The edge position of the resist film R1 is, for example, the position of an outer end of the resist film R1.

The circumferential position is specified by an angle from the index portion (reference position) such as the notch mentioned above in the circumferential direction around the center of the wafer W, for example. The edge position of the resist film R1 is specified by, for example, the shortest distance between the center (central axis CL) of the wafer W and the edge of the resist film R1. The edge (outer end) of the resist film R1 is located inside the outer end of the front surface Wa of the wafer W. Therefore, the edge position of the resist film R1 may be specified by the shortest distance between a theoretical position of the outer end of the front surface Wa and the edge of the resist film R1. The shortest distance between the theoretical position of the outer end of the front surface Wa and the edge of the resist film R1 corresponds to the width of the removed portion of the resist film R, so it can also be referred to as a cut width. The following description will be provided for an example case where the edge position of the resist film R1 is calculated as the cut width.

In the captured peripheral image PI shown in FIG. 7A, the edge (outer end) of the resist film R1 is denoted by “E1”, and the theoretical position of the outer end of the front surface Wa is denoted by “E0”. Furthermore, the circumferential direction around the center of the wafer W is denoted by “θ”, and the radial direction of the wafer W is denoted by “r”.

When generating the edge information, the information acquirer 212 may calculate the edge position of the resist film R1 for each predetermined angle in the circumferential direction. The information acquirer 212 may calculate the edge position of the resist film R1 for each arbitrary angle (e.g., 1°) between 0.5° and 30°. In the captured peripheral image PI, the position of the index portion on the wafer W may be set to 0°. The information acquirer 212 may calculate the edge position of the resist film R1 from the captured peripheral image PI by any of various image processing methods.

Due to various factors, the edge position of the resist film R1 varies depending on the circumferential position, that is, depending on the angle from the index portion. FIG. 7B shows an example of the edge information, in which each of a plurality of circumferential positions having different values is matched with the edge position at the corresponding circumferential position. Here, instead of calculating the edge position by itself, the information acquirer 212 may acquire it from the outside (for example, the control device 100). That is, the edge information may be generated by calculating the edge position in the control device 100.

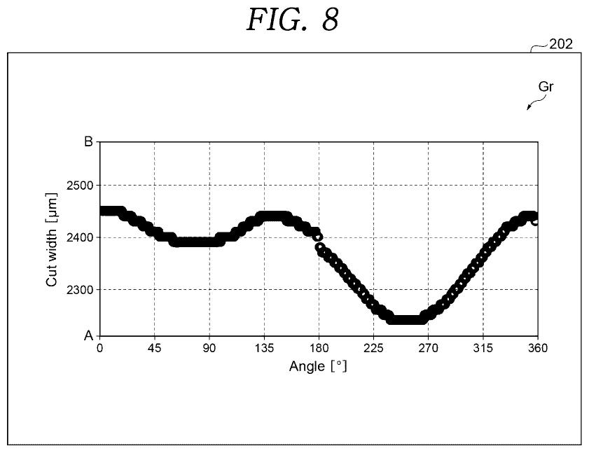

Based on the edge information, the information display 214 displays, on the monitor 202, a graph Gr indicating the edge position for each circumferential position. FIG. 8 shows an example of the graph Gr displayed on the monitor 202. The graph Gr visually shows the relationship between the circumferential position (angle from the index portion) and the edge position. As illustrated in FIG. 8, the graph Gr may be a graph of rectangular coordinates (two-dimensional rectangular coordinates) in which a vertical axis represents the edge position and a horizontal axis represents the circumferential position.

The graph Gr illustrated in FIG. 8 is a scatter plot, and is drawn by plotting each value of the edge position included in the edge information. The vertical axis indicating the edge position may be a linear scale on which the values (plot positions) are equi-spaced. The horizontal axis indicating the circumferential position may also be a linear scale. The information display 214 displays the graph Gr on the monitor 202 according to a display range determined by the range determiner 216. Below, an example of a method of displaying the graph Gr will be described along with an explanation of the range determiner 216.

Before displaying the graph Gr on the monitor 202, the range determiner 216 determines the display range for the edge positions on the graph Gr based on the statistical information of the edge positions included in the edge information. Determining the display range means determining maximum and minimum values of the edge positions on the graph Gr. In the graph (scatter plot) of the rectangular coordinates illustrated in FIG. 8, the display range for the edge positions is determined by determining the maximum and minimum values on the vertical axis.

In FIG. 8, the minimum value of the edge position on the graph Gr is denoted by “A” and the maximum value is denoted by “B”. In addition, since the maximum and minimum values are only required to decide the range of the vertical axis (that is, the range of the vertical axis is decided based on the determined maximum and minimum values), the maximum and minimum values themselves may or may not be displayed on the graph Gr. In FIG. 8, “A” and “B” are used for the convenience of explanation. In the drawings other than FIG. 8, when “A” and “B” are used, they represent a minimum value and a maximum value, respectively.

Even if the values of the edge positions included in the edge information are the same, the shape formed by plotting the edge positions (hereinafter referred to as “edge plot shape”) looks different depending on the minimum value A and the maximum value B. Specifically, if a difference between the maximum value B and the minimum value A is large, a variation in the edge position in the edge plot shape may become small on the graph Gr. If, on the other hand, the difference between the maximum value B and the minimum value A is small, the variation in the edge position in the edge plot shape may become large on the graph Gr.

The information display 214 displays the graph Gr not only for one wafer W but also for each of a plurality of wafers W. In this case, the range determiner 216 determines the display range for the edge positions for each of the wafers W. It is assumed that obtained edge information may differ between the wafers W, and the display range for the edge positions on the graph Gr may also differ due to such difference in the edge information. The information display 214 may display the graph Gr such that the size of the graph Gr itself on the monitor 202 is constant even if the display range for the edge positions differs.

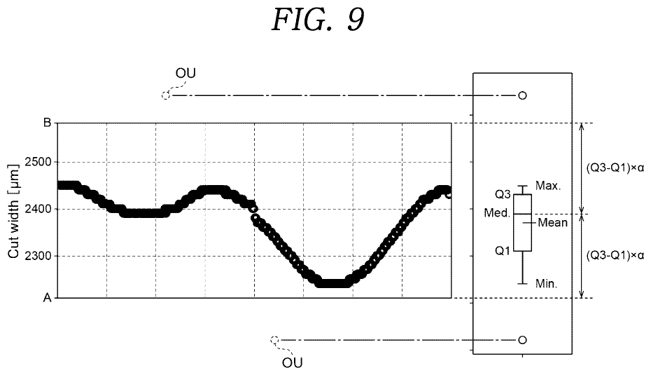

The statistical information for determining the display range for the edge positions may include at least some of five-number summary obtained when creating a box-and-whisker diagram for the edge positions from the edge information. The statistical information may include a first quartile, a median (second quartile), and a third quartile among the five-number summary. The range determiner 216 may determine the display range based on a difference between the third quartile and the first quartile (interquartile range) and the median. FIG. 9 illustrates an example of a relationship between the statistical information based on the box-and-whisker diagram and the graph Gr displayed on the monitor 202.

When the first quartile is denoted as “Q1”, the median (second quartile) as “Med”, and the third quartile as “Q3”, the range determiner 216 may determine the minimum value A and the maximum value B according to the following expressions (1) and (2).

$$A = Med - \{ ( Q 3 - Q 1 ) \times α \} \qquad ( 1 )$$

$$B = Med + \{ ( Q 3 - Q 1 ) \times α \} \qquad ( 2 )$$

In the expressions (1) and (2), a denotes a constant greater than 1. In order to avoid that necessary data in the edge information is not displayed, a may be 1.1 or more, 1.2 or more, 1.3 or more, or 1.4 or more. When observing a change in the edge position according to a change in the circumferential position, in order to make it easier for the operator or the like who has observed the graph Gr to grasp the change in the edge position, a may be set to be 2.0 or less, 1.8 or less, 1.7 or less, or 1.6 or less. By setting a to be 1.5 or less, it is possible to suppress an outlier OU based on the box-and-whiskers diagram from being displayed on the graph Gr. For example, a is greater than 1.0 and equal to or less than 2.0, or is in the range of 1.1 to 1.8 or 1.4 to 1.6.

The range determiner 216 may use an average instead of the median to determine the minimum value A and the maximum value B. When the average is expressed as “Mean”, the range determiner 216 may determine the minimum value A and the maximum value B by using the following expressions (3) and (4).

$$A = Mean - \{ ( Q 3 - Q 1 ) \times α \} \qquad ( 3 )$$

$$B = Mean + \{ ( Q 3 - Q 1 ) \times α \} \qquad ( 4 )$$

As described above, the range determiner 216 may determine the display range based on the median or the average of the edge positions included in the edge information and a value obtained by multiplying the difference between the third quartile and the first quartile by a constant greater than 1. Here, a may be a fixed constant, or may be adjustable by the operator before plotting the graph Gr.

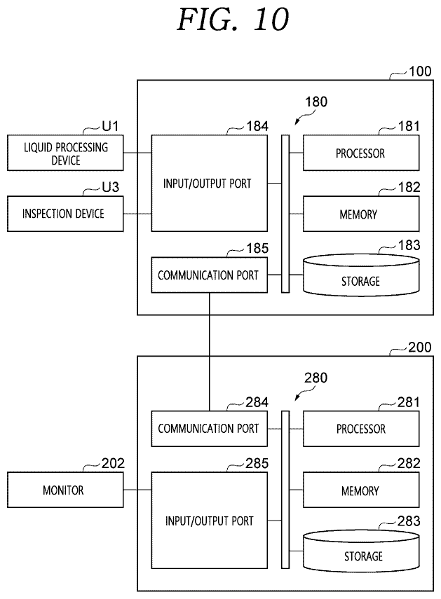

FIG. 10 shows an example of a hardware configuration of the control device 100 and the display device 200. The control device 100 includes a circuit 180. The circuit 180 has a processor 181, a memory 182, a storage 183, an input/output port 184, and a communication port 185. The storage 183 is composed of one or more non-volatile memory devices such as a flash memory and a hard disk. The storage 183 stores a program for configuring each functional block of the control device 100.

The memory 182 is composed of one or more volatile memory devices such as, but not limited to, a random access memory. The memory 182 temporarily stores the program loaded from the storage 183. The processor 181 is composed of one or more operational devices such as a CPU (Central Processing Unit) and a GPU (Graphics Processing Unit). The processor 181 executes the program loaded into the memory 182 to configure each functional block of the control device 100. The operation result by the processor 181 is temporarily stored in the memory 182. The input/output port 184 performs input/output of information to/from the liquid processing device U1, the inspection device U3, and so forth, in response to a request from the processor 181. The communication port 185 communicates with the display device 200 via a wired, wireless, or communication network, in response to a request from the processor 181.

The display device 200 includes a circuit 280. The circuit 280 has a processor 281, a memory 282, a storage 283, an input/output port 284, and a communication port 285. The storage 283 is composed of one or more non-volatile memory devices such as a flash memory and a hard disk. The storage 283 stores a program for configuring each functional block of the display device 200. The storage 283 stores a display program for causing a computer to perform at least the following operations: acquiring the edge information indicating the relationship between the circumferential position and the edge position of the resist film R1 in the radial direction of the wafer W for each of the multiple circumferential positions based on the captured peripheral image PI; displaying, on the monitor 202, the graph Gr indicating the edge position for each circumferential position based on the edge information; and determining the display range for the edge positions on the graph Gr based on the statistical information of the edge positions included in the edge information before displaying the graph Gr on the monitor 202.

The memory 282 is composed of one or more volatile memory devices such as, but not limited to, a random access memory. The memory 282 temporarily stores the program loaded from the storage 283. The processor 281 is composed of one or more operational devices such as a CPU (Central Processing Unit) and a GPU (Graphics Processing Unit). The processor 281 executes the program (display program) loaded into the memory 282 to configure each functional block of the display device 200. An operation result by the processor 281 is temporarily stored in the memory 282. The input/output port 284 performs input/output of information to/from the monitor 202 so forth, in response to a request from the processor 281. The communication port 285 communicates with the control device 100 via a wired, wireless or communication network, in response to a request from the processor 281.

The display program may be provided by being fixedly recorded on a tangible recording medium such as a CD-ROM, a DVD-ROM, or a semiconductor memory. Alternatively, the display program may be provided via a communication network as a data signal superimposed on a carrier wave. At least one of the control device 100 and the display device 200 may be composed of a plurality of computers connected to each other so as to be able to communicate with each other. The control device 100 and the display device 200 may be implemented by a single computer. For example, by adopting a configuration in which the monitor 202 is connected to the control device 100, and the control device 100 has the information acquirer 212, the information display 214 and the range determiner 216, the control device 100 may function as a display device. The display device 200 may display the graph Gr on a monitor connected to another computer.

### <Display Method>

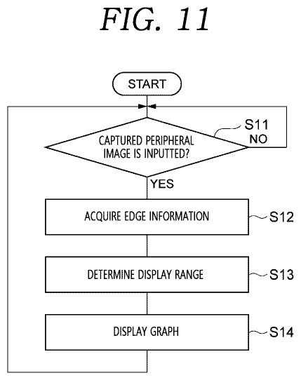

Now, a display method performed in the display device 200 will be explained with reference to FIG. 11. As shown in FIG. 11, the display device 200 first performs a process S11. For example, in the process S11, the display device 200 stands by until the captured peripheral image PI is inputted. As one example, every time an inspection process is performed to inspect the front surface Wa of the wafer W including the resist film R1 (the resist film R from which the peripheral portion is removed), the captured peripheral image PI is inputted to the display device 200 from the imaging controller 118 of the control device 100.

Next, the display device 200 performs a process S12. For example, in the process S12, the information acquirer 212 acquires the edge information by calculating the edge position of the resist film R1 for each of the multiple circumferential positions around the center of the wafer W based on the captured peripheral image PI. The information acquirer 212 may calculate the edge position after detecting the edge based on a variation in a pixel value for each circumferential position (for example, for each predetermined angle) on the image. The information acquirer 212 may calculate, as the edge position of the resist film R1, the cut width indicating the edge position from the theoretical circumference of the front surface Wa of the wafer W for each circumferential position. The smaller the cut width, the closer the outer end of the resist film R1 at that circumferential position is to the circumference of the front surface Wa, and the larger the cut width, the farther the outer end of the resist film R1 at that circumferential position is from the circumference of the front surface Wa.

Then, the display device 200 performs a process S13. For example, in the process S13, the range determiner 216 determines the display range for the edge positions on the graph Gr to be displayed on the monitor 202 in a next process S14. As one example, the range determiner 216 calculates the minimum value A and the maximum value B for the cut width by using the above-described expressions (1) and (2), or by using the above-described expressions (3) and (4).

Subsequently, the display device 200 performs the process S14. For example, in the process S14, the information display 214 displays, on the monitor 202, the graph Gr showing the variation in the cut width for the variation in the circumferential position from the edge information obtained in the process S12, according to the determination result of the display range obtained in the process S13. This allows the operator or the like to check an edge state (for example, the result after the removal with the processing liquid L2) at the peripheral portion of the wafer W as an inspection target. Thereafter, the processing performed by the display device 200 returns to the process S11, and the display device 200 repeats the series of processes S12 to S14 as the inspection of the wafer W is repeated.

### Modification Examples

The series of processes shown in FIG. 11 is an example and may be modified appropriately. In the series of processes, the display device 200 may perform one process and the next process in parallel, or may perform the respective processes in an order different from the one described above. The display device 200 may skip any one of the above-described processes. In the series of processes described above, the display device 200 may perform a process different from the one described above.

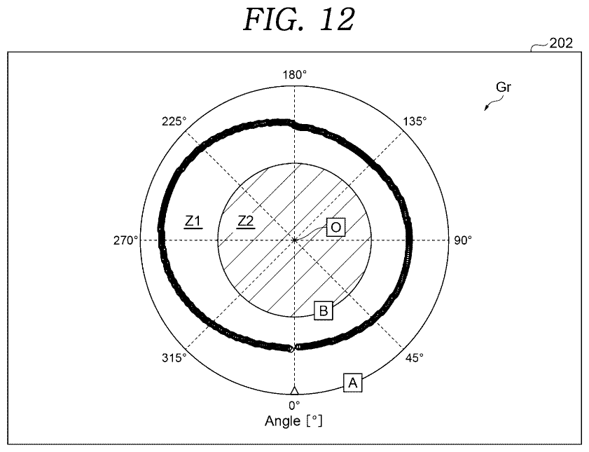

The format of the graph Gr is not limited to the rectangular coordinates. The graph Gr displayed on the monitor 202 by the information display 214 may be a polar coordinate graph in which a distance from the origin represents an edge position and an angle (polar angle) around the origin represents a circumferential position, as shown in FIG. 12. The graph Gr illustrated in FIG. 12 is a scatter plot in the form of polar coordinates, and the graph Gr is drawn by plotting the respective values of the edge positions included in the edge information. When focusing on one piece of data consisting of one circumferential position and one edge position in the edge information, the position where this data is plotted is determined by the circumferential position and the edge position. That is, on the graph Gr, the angle around the origin is specified by the circumferential position, and the distance from the origin is specified by the edge position. In FIG. 12, for the sake of explanation, the origin of the graph Gr is denoted by “O”.

The distance from the origin representing the edge position may be a linear scale on which the values (plot positions) are equi-spaced. When the edge position is represented by the cut width, the information display 214 may create the graph Gr such that the cut width decreases as the distance from the origin of the graph Gr increases. When the edge position is represented by the distance from the center of the wafer W, the information display 214 may create the graph Gr such that the distance from the center of the wafer W increases as the distance from the origin of the graph Gr increases.

The graph Gr may include a display area Z1 and a non-display area Z2. The display area Z1 is an area of the graph Gr where the data representing the edge positions included in the edge information is plotted. The non-display area Z2 is an area of the graph Gr where no data representing the edge positions included in the edge information is plotted. The non-display area Z2 is a circular area including the origin of the graph Gr and located at the center. The center of the circular non-display area Z2 coincides with the origin of the graph Gr. The display area Z1 is an annular area that surrounds the non-display area Z2. The radius of the non-display area Z2 may be 0.9 times to 1.1 times, 0.95 times to 1.05 times, or 0.98 times to 1.02 times the width (the shortest distance between an inner end and an outer end of the display area Z1) of the display area Z1. For example, the radius of the non-display area Z2 is equal to the width of the display area Z1.

When the graph Gr of the polar coordinates is displayed on the monitor 202, the information display 214 displays the graph Gr on the monitor 202 according to the display range determined by the range determiner 216. The range determiner 216 determines the maximum and minimum values of the edge position on the graph Gr of the polar coordinates based on the statistical information of the edge position included in the edge information. In FIG. 12, the maximum value of the edge position is denoted by “B” and the minimum value of the edge position is denoted by “A”. Also, the origin of the graph is denoted by “O”. When the radius of the non-display area Z2 is equal to the width of the display area Z1, the value of the origin O is calculated by an expression of “B+(B−A)”.

In the example shown in FIG. 12 (the example where the cut width is displayed), the circumference corresponding to the inner end of the annular display area Z1 corresponds to the maximum value B, and the circumference corresponding to the outer end of the display area Z1 corresponds to the minimum value A. The same as in the case of the graph Gr (scatter plot) of the rectangular coordinates, the size representing the change in the edge position in the edge plot shape on the graph Gr differs depending on the setting of the minimum value A and the maximum value B. The range determiner 216 may calculate the minimum value A and the maximum value B by using the above-described expressions (1) and (2). Still alternatively, the range determiner 216 may calculate the minimum value A and the maximum value B by using the above-described expressions (3) and (4) instead of the expressions (1) and (2).

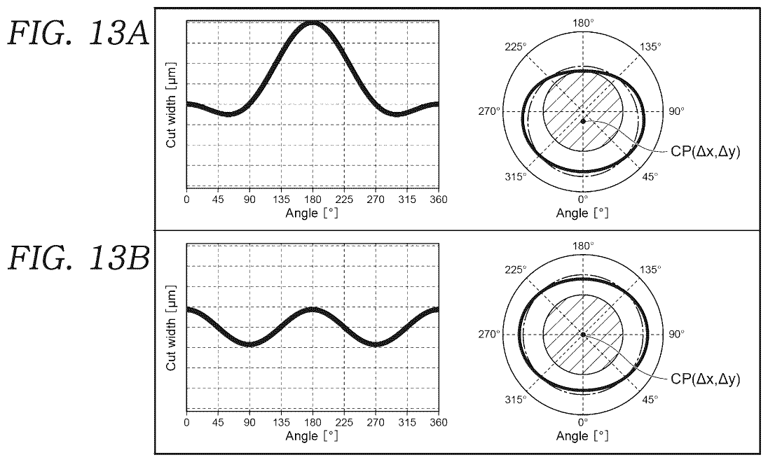

Now, with reference to FIG. 13A and FIG. 13B, the advantage of displaying the graph Gr on the monitor 202 in the polar coordinate format as illustrated in FIG. 12 will be explained. In the inspection of the wafer W using the captured peripheral image PI, the operator or the like evaluates from the edge information whether the edge shape of the resist film R1 is appropriate or not. One example of an inappropriate edge shape may be “eccentricity,” which means that the center of the edge shape is misaligned with respect to the center of the wafer W. When the edge shape is eccentric, the position of the wafer transfer device 33 is adjusted when the wafer W is transferred from the wafer transfer device 33 to the holder 52 of the liquid processing device U1, for example.

In each of FIG. 13A and FIG. 13B, for the sake of explanation, a graph of rectangular coordinates is shown on the left and a graph of polar coordinates is shown on the right. FIG. 13A illustrates a graph based on the edge information obtained before the position of the wafer transfer device 33 is adjusted, and FIG. 13B illustrates a graph based on the edge information obtained after the position of the wafer transfer device 33 is adjusted. When the graph of rectangular coordinates is displayed on the monitor 202, the operator or the like needs to understand from the graph on the left in FIG. 13A that eccentricity has occurred. In this case, the operator or the like needs to imagine (visualize) in their mind an actual edge shape from the graph of rectangular coordinates.

Meanwhile, in the graph of polar coordinates on the right side in FIG. 13A, a shape close to the actual edge shape is displayed on the monitor 202. Therefore, the operator or the like can immediately grasp the edge shape by looking at the graph on the monitor 202 without having to imagine the edge shape in their mind. In addition, in the graphs on the right side of FIG. 13A and FIG. 13B, the center of the edge shape is denoted by “CP(Δx, Δy)”. As compared to FIG. 13A, in the graph on the right side of FIG. 13B, CP(Δx, Δy) is found to be closer to the origin of the graph.

Another example of an inappropriate edge shape is when the edge shape becomes an “ellipse” instead of a circle. In the graphs on the right side of FIG. 13A and FIG. 13B, a dashed dotted line represents a circle centered on the center of the edge shape. Whether or not the edge shape is an ellipse can also be more easily grasped from the graph of polar coordinates than from the graph of rectangular coordinates. For example, in order to be able to determine whether the edge shape is an ellipse from the graph of rectangular coordinates, a certain level of expertise is required. In contrast, by displaying the graph of polar coordinates on the monitor 202, even an inexperienced operator can easily investigate whether or not the edge shape is an ellipse.

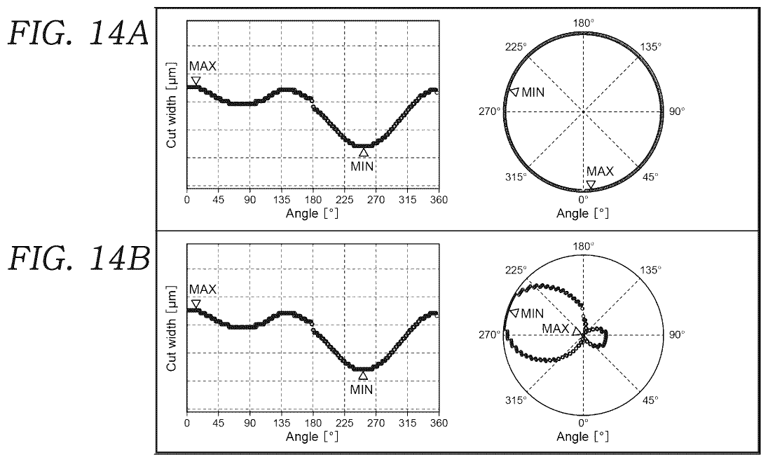

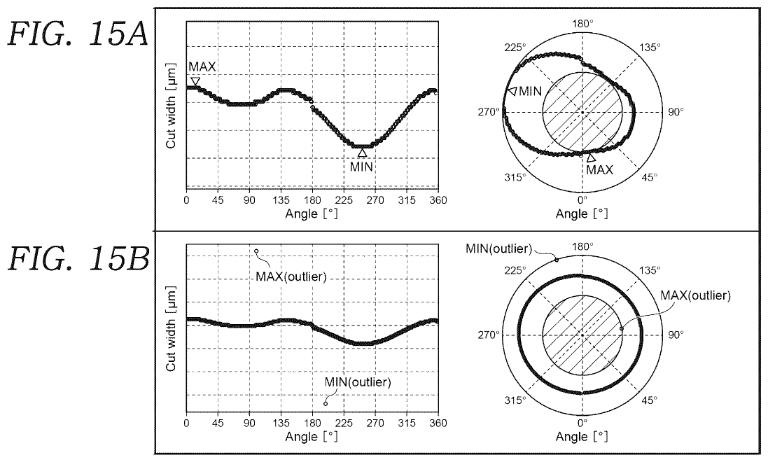

As a result of various examinations, it is found that by providing the display area Z1 and the non-display area Z2 in the graph Gr of polar coordinates and setting the minimum value A and maximum value B as described above (see FIG. 12), the edge shape on the graph Gr can be made closer to the actual shape. Here, graphs created during the examination process will be explained with reference to FIG. 14A to FIG. 15B. In each of FIG. 14A to FIG. 15B, for the sake of easy understanding, a graph of rectangular coordinates is shown next to a graph of polar coordinates. In each of FIG. 14A and FIG. 14B and each of FIG. 15A and FIG. 15B, “MAX” denotes the maximum value of the edge position in the edge information, and “MIN” denotes the minimum value of the edge position in the edge information.

In the graph of polar coordinates shown in FIG. 14A, the origin is set to be 0 mm, and the outermost circumference is set to be 150 mm, which is an example of the radius of the wafer W. The edge position is a distance from the center of the wafer W. An example of the cut width at the peripheral region of the front surface Wa is about 1/300 times to about 1/50 times the radius of the wafer W. Therefore, it is difficult to grasp the change in the edge position with respect to the change in the circumferential position from the graph of polar coordinates shown in FIG. 14A.

Following the example shown in FIG. 14A, the graph of polar coordinates shown in FIG. 14B is created and examined. In the graph of polar coordinates shown in FIG. 14B, the edge position is the cut width, the origin is set to the maximum value in measurement results (edge information), and the outermost circumference is set to the minimum value in the measurement results (edge information). The entire circular area including the origin is set as an area where data is plotted. In this case, since the origin of the graph is the maximum value of the measurement results (maximum value of the cut width), if the plot shape of the graph has two or more peaks, an extremely narrow portion will appear in the graph of polar coordinates.

Based on the examination result in the graph shown in FIG. 14B, the display area Z1 and the non-display area Z2 are set in the graph of polar coordinates, as illustrated in FIG. 15A. In the graph of polar coordinates shown in FIG. 15A, the edge position is a cut width, the circumference corresponding to the inner end of the display area Z1 is set to be the maximum value of the measurement result (edge information), and the circumference corresponding to the outer end of the display area Z1 is set to be the minimum value of the measurement result (edge information). In this case, although the sense of incongruity is reduced compared to the graph shown in FIG. 14B, a distortion from the actual edge shape (ellipse) remains. For example, the distortion is large at a portion close to the maximum value of the measurement result.

FIG. 15B shows a graph of polar coordinates drawn under the same conditions as the graph shown in FIG. 15A when the measurement result (edge information) includes an outlier. “MAX (outlier)” denotes a maximum value of the measurement result and indicates that it is an outlier, and “MIN (outlier)” denotes a minimum value of the measurement result and indicates that it is an outlier. In this case, the minimum and maximum values in the display range of the graph are set as outliers, making it difficult to grasp from the graph a change in the edge position with respect to a change in the circumferential position.

Based on the examination results shown in FIG. 15A and FIG. 15B, the minimum value A and the maximum value B of the edge position on the graph are set by using the expressions (1) and (2), or the expressions (3) and (4). In the graph Gr (see FIG. 12), for which the conditions for drawing are determined through the above-described examination process, a distortion from the actual edge shape (ellipse) is small, and it is difficult to be affected by the outliers.

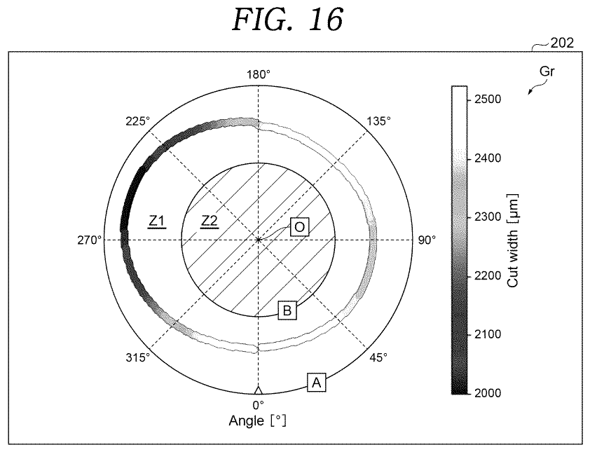

FIG. 16 shows another example of the graph Gr displayed on the monitor 202. The information display 214 may display the graph Gr on the monitor 202 such that points respectively corresponding to the multiple circumferential positions to indicate the edge position are displayed in different colors according to the size of the corresponding edge position. In the graph shown in FIG. 16, differences in color are expressed by shading. For example, the color of the plotted points is set such that the color is gradated in the order of red, orange, yellow, green, blue, and purple as the cut width decreases from the maximum value. In this case, the difference in color makes it easier to grasp a place where the cut width is small and a place where the cut width is large.

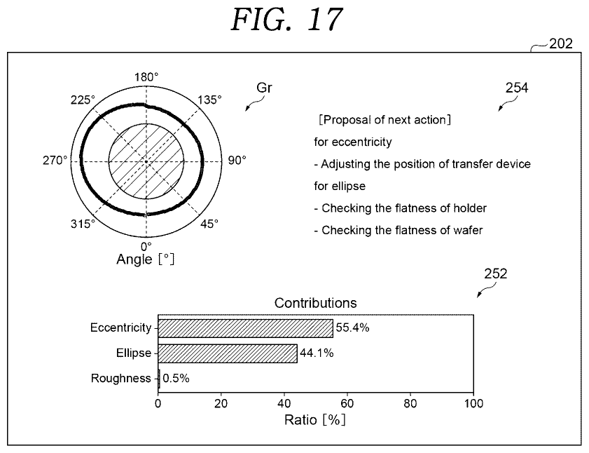

FIG. 17 presents another example of the monitor 202 with the graph Gr displayed thereon. The information display 214 may display relevant information obtained from the edge information on the monitor 202, in addition to the graph Gr. The information display 214 may display first relevant information 252 on the monitor 202 along with the graph Gr. The first relevant information 252 is information indicating a contribution rate of each factor to the non-uniformity in the edge position in one edge information (one wafer W). The degree of the non-uniformity in the edge position may be evaluated by calculating, for example, a standard deviation σ. However, it is not possible to find out from a calculation value of the standard deviation which factor has caused the non-uniformity and to what extent that factor has contributed.

The non-uniformity in the edge position in the edge information includes, as factors, a first component, a second component, and a residual component. The first component is a component caused by eccentricity (non-uniformity resulting from eccentricity), which indicates the deviation between the center of the wafer W and the center of the edge shape obtained by the set of edge positions at the multiple circumferential positions. The second component is a component caused by the edge shape being the ellipse (non-uniformity resulting from elliptical edge shape). The residual component is a component caused by a residual (non-uniformity resulting from residual) other than the first and second components. The residual component is mainly a component caused by roughness, which indicates minute fluctuations (irregularity) at the edge.

The display device 200 may have, as a functional block, a contribution rate calculator 222 (see FIG. 5). The contribution rate calculator 222 calculates a contribution rate of the first component, a contribution rate of the second component, and a contribution rate of the residual component. By way of example, the contribution rate calculator 222 may perform polynomial model fitting of the edge information and calculate the contribution rates based on coefficients of a polynomial expression (approximate equation) obtained by the model fitting.

The following expression (5) is an example of the approximation equation used in the polynomial model fitting. In the expression (5), w denotes a variable indicating a cut width (edge position), and θ represents a variable that represents a circumferential position. Also, w0 is a constant, and (−c1), (−s1), (−c2), and (−s2) are coefficients. By the model fitting, the coefficients (−c1), (−s1), (−c2), and (−s2) are calculated according to the edge information. An eccentric position in the edge shape can be calculated by using (−c1) and (−s1), and an elliptical angle and an elliptical amplitude can be calculated by using (−c2) and (−s2).

$$[ Formula 1 ]$$

$$w = w 0 + ( - c 1 ) cos θ + ( - s 1 ) sin θ + ( - c 2 ) cos 2 θ + ( - s 2 ) sin 2 θ \qquad ( 5 )$$

When calculating the contribution rate of each component, the contribution rate calculator 222 first standardizes each cut width included in the edge information such that an average becomes 0 and a standard deviation becomes 1. That is, the contribution rate calculator 222 standardizes each calculation value of the cut width by subtracting an average u of the cut width from the calculation value and dividing a value obtained by the subtraction by the standard deviation σ of the cut width. For the standardized cut width, the contribution rate calculator 222 calculates the coefficients of the approximate equation in the expression (5) by the model fitting.

The contribution rate calculator 222 calculates the contribution rates of the first component, the second component, and the residual component by using the following expressions (6) to (8) after standardizing the cut width and calculating the coefficients of the approximate equation. In the expressions (6) to (8), the square of r means a coefficient of determination of a multiple regression equation.

$$[ Formula 2 ]$$

$$Contribution rate of first component : {r}^{2} \frac{\vert c 1 + s 1 \vert}{\vert c 1 + s 1 + c 2 + s 2 \vert} \qquad ( 6 )$$

$$Contribution rate of second component : {r}^{2} \frac{\vert c 2 + s 2 \vert}{\vert c 1 + s 1 + c 2 + s 2 \vert} \qquad ( 7 )$$

$$Contribution rate of residual component : 1 - {r}^{2} \qquad ( 8 )$$

The information display 214 may display second relevant information 254 on the monitor 202 in addition to the graph Gr and the first relevant information 252. The second relevant information 254 includes information indicating an identification result of the type of abnormality that exists between an edge shape obtained from the edge information (measured actual edge shape) and a theoretical edge shape. The theoretical edge shape is, for example, a circle whose center coincides with the center of the wafer W and whose radius is of a set value. The second relevant information 254 includes information indicating a candidate for a countermeasure according to the identification result of the type of the abnormality.

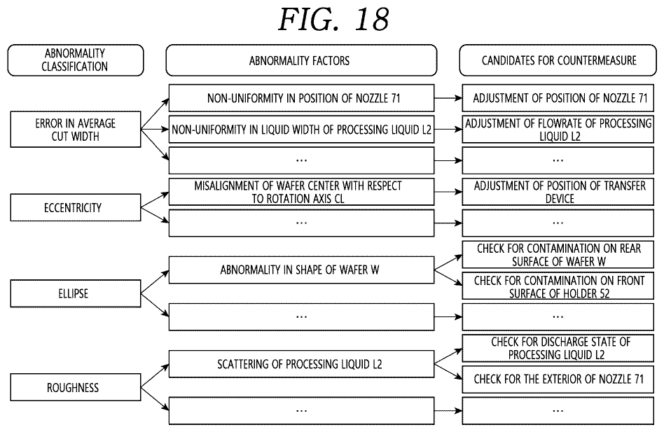

FIG. 18 presents an example of a relationship between categories of abnormalities of the edge shape obtained from the edge information and factors of those abnormalities, and a relationship between the factors of the abnormalities and candidates for countermeasure therefor. The categories of the abnormalities include, by way of example, having an error in an average cut width, having eccentricity, being an ellipse, and having roughness (fine fluctuations) at the edge. The categories of the abnormalities and the candidates for countermeasure corresponding to those categories of the abnormalities are matched in advance. Two or more candidates for countermeasure may be matched with one or more categories of the abnormalities. The display device 200 may store information (hereinafter, referred to as “matched information”) in which the categories of the abnormalities are matched with the candidates for countermeasure for resolving those abnormalities. The matched information does not need to include the factors of the abnormalities listed in FIG. 18.

The display device 200 may have, as functional blocks, an abnormality identifier 224 and a countermeasure candidate determiner 226 (see FIG. 5). After the information acquirer 212 acquires the edge information, the abnormality identifier 224 identifies the type of the abnormality that exists between the edge shape obtained by the set of the edge positions at the multiple circumferential positions and the theoretical edge shape.

After calculating an average of the edge positions from the edge information, the abnormality identifier 224 may compare the arithmetic mean of the edge positions with a set value to determine whether or not an error is included in the average cut width. The abnormality identifier 224 may classify the abnormality as eccentricity when a value of three times the standard deviation is equal to or greater than a predetermined value and the contribution rate of the first component is equal to or greater than a preset value. The abnormality identifier 224 may classify the abnormality as an ellipse when the value of three times the standard deviation is equal to or greater than a predetermined value and the contribution rate of the second component is equal to or greater than a preset value. The abnormality identifier 224 may classify the abnormality as roughness when the value of three times the standard deviation is equal to or greater than a predetermined value and the contribution rate of the residual component is equal to or greater than a preset value.

After the abnormality identifies 224 identifies the type of the abnormality, the countermeasure candidate determiner 226 may determine a candidate for countermeasure according to the identification result of the type of the abnormality based on the aforementioned matched information. The information display 214 may display on the monitor 202 the identification result of the type of the abnormality and the determination result of the candidate for the countermeasure as the second relevant information 254.

As illustrated in FIG. 17, the abnormality identifier 224 may specify two or more abnormality categories. The countermeasure candidate determiner 226 may determine two or more candidates for countermeasure for one abnormality category. By displaying the identification result of the abnormality classification and the determination result of the candidates for countermeasure for resolving the abnormality on the monitor 202, even an unexperienced operator can easily come up with a countermeasure that should be prioritized. In the example shown in FIG. 17, eccentricity and ellipse are identified as abnormality categories.

The information display 214 may display, instead of both the first relevant information 252 and the second relevant information 254, either the first relevant information 252 or the second relevant information 254 together with the graph Gr on the monitor 202. The information display 214 may display the first relevant information 252 and the second relevant information 254 on the monitor 202 separately from a screen on which the graph Gr is displayed. As one example, based on a user input, the information display 214 may perform a switchover between a screen displaying the graph Gr and a screen displaying at least one of the first relevant information 252 and the second relevant information 254.

The information display 214 may display, together with the graph Gr, other information on the monitor 202 in addition to or instead of the first relevant information 252 and the second relevant information 254. The other information displayed on the monitor 202 include, for example, an arithmetic mean of the cut width, a center of the edge shape (eccentric position), an elliptical angle, an elliptical amplitude, a standard deviation indicating the degree of non-uniformity, and other statistical information of the edge position (an average value, a range, a maximum value, and a minimum value).

The display device 200 may not have a function of creating a scatter plot of polar coordinates, but may have a function of creating a scatter plot of rectangular coordinates. In this case, the information display 214 may convert each edge position determined by the edge information into rectangular coordinates and then create the graph Gr of polar coordinates as shown in FIG. 12. That is, the graph Gr of polar coordinates needs to be a graph in which, when displayed on the monitor 202, information indicating the edge position is represented by a distance from the origin and an angle around the origin.

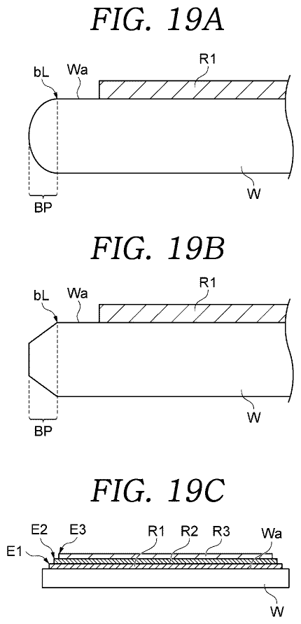

As illustrated in FIG. 19A and FIG. 19B, a bevel portion BP may be formed at an outer periphery of the wafer W. The bevel portion BP is a portion formed by chamfering at the outer periphery of the wafer W. As shown in FIG. 19A, the bevel portion BP may be formed by chamfering the wafer W so that the outer end thereof is gently curved when viewed from the side. As shown in FIG. 19B, the bevel portion BP may be formed by chamfering the wafer W so that inclined planes are formed on the front and rear surfaces thereof.

In the present disclosure, when the bevel portion BP is formed at the outer periphery of the wafer W, the “front surface” of the wafer W also includes the bevel portion BP when viewed from the front surface Wa side. In this case, the front surface Wa includes a substantially flat plane portion and a curved or inclined surface (a portion that can be seen from the front surface Wa side) of the bevel portion BP. In each of FIG. 19A and FIG. 19B, “bL” represents a boundary between the bevel portion BP and a portion other than the bevel portion BP on the front surface Wa. The boundary bL extends along the circumferential direction around the center of the wafer W. When the bevel portion BP is formed, the edge position of the resist film R1 is located inside the boundary bL. The bevel portion BP may be included in the captured peripheral image PI, which is an image obtained by imaging the peripheral region on the front surface Wa of the wafer W.

As shown in FIG. 19C, a plurality of resist films may be formed on the front surface Wa of the wafer W. A peripheral portion of each of the plurality of resist films may be removed by the processing liquid L2 or the like. In the example shown in FIG. 19C, a resist film R1, a resist film R2, and a resist film R3 are formed on the front surface Wa as a plurality of resist films from which peripheral portions thereof are already removed. The resist film R1, the resist film R2, and the resist film R3 are formed so as to overlap in this order from the front surface Wa. In FIG. 19C, “E1” denotes an edge (outer end) of the resist film R1; “E2,” an edge (outer end) of the resist film R2; and “E3,” an edge (outer end) of the resist film R3.

The information acquirer 212 of the display device 200 may acquire edge information for the edge E1, edge information for the edge E2, and edge information for the edge E3. The edge information for the edge E1 is information that indicates a relationship between a circumferential position and a position of the edge E1 in a radial direction for each of multiple circumferential positions. The captured peripheral image PI for obtaining the edge information for the edge E1 may be obtained before the resist film R2 and the resist film R3 are formed.

The edge information for the edge E2 is information indicating a relationship between a circumferential position and a position of the edge E2 in the radial direction for each of the multiple circumferential position. The captured peripheral image PI for obtaining the edge information for the edge E2 may be obtained before the resist film R3 is formed. The edge information for the edge E3 is information indicating a relationship between a circumferential position and a position of the edge E3 in the radial direction for each of the multiple circumferential positions. Only the edge information for the edge E3 may be obtained from the captured peripheral image PI obtained after the resist film R3 is formed, or the edge information for each of the edges E1, E2, and E3 may be obtained.

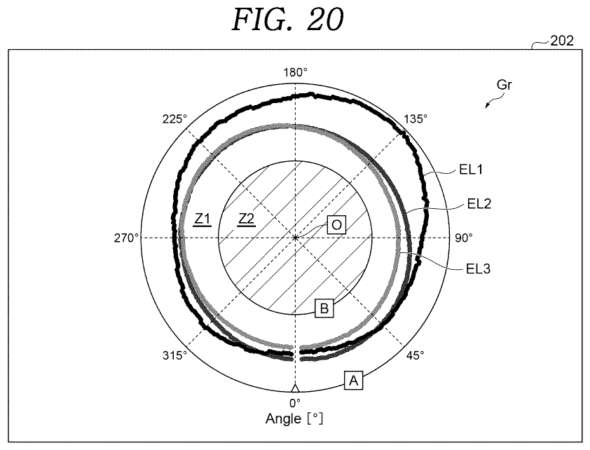

As depicted in FIG. 20, the information display 214 may display, on the monitor 202, the graph Gr including the information indicating the edge position of the edge E1, the information indicating the edge position of the edge E2, and the information indicating the edge position of the edge E3. In FIG. 20, “EL1” denotes a group of plots (a group of points) indicating the edge position of the edge E1, and is drawn on the graph Gr based on the edge information of the edge E1. “EL2” means a group of plots indicating the edge position of the edge E2, and is drawn on the graph Gr based on the edge information of the edge E2. “EL3” denotes a group of plots (a group of points) indicating the edge position of the edge E3, and is drawn on the graph Gr based on the edge information of the edge E3. The group of plots means a set of individual points (individual data points).

The minimum value A and the maximum value B that define the display range of the graph Gr may be determined from edge information (hereinafter referred to as “combined edge information”) that combines all of the edge information for the edge E1, the edge information for the edge E2, and the edge information for the edge E3. The range determiner 216 may calculate statistical information from the combined edge information and then determine the minimum value A and the maximum value B by using the above-described expressions (1) and (2) or the above-described expressions (3) and (4). Alternatively, the range determiner 216 may specify the minimum value A and the maximum value B for each edge and then determine a range defined by an arithmetic mean of the minimum value A and an arithmetic mean of the maximum value B as the display range of the graph Gr. By displaying the information of the multiple edges on the graph Gr simultaneously, the operator or the like can easily understand the relationship between the edge shapes.

When displaying the information for the multiple edges on the graph Gr, it may be possible to switch to a screen that displays detailed information on a specified edge among the multiple edges in response to an input from a user such as the operator. In the example screen illustrated in FIG. 20, it may be possible for the user to specify an edge. For example, the user may be able to select a group of plots for each edge on the graph Gr by pressing or other operations, and a button for selecting the edge may be displayed on the screen, separately from the graph Gr.

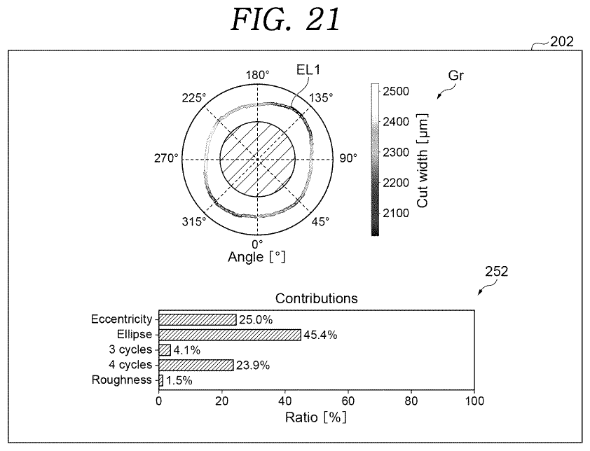

FIG. 21 shows an example of a screen switched after the edge E1 is selected by the user. After the user's selection, the information display 214 may display on the monitor 202 the graph Gr showing the edge position of only the selected edge E1. At this time, the range determiner 216 may recalculate the minimum value A and the maximum value B, taking into account only the edge information for the edge E1, and then change the display range of the edge position on the graph Gr. After the user's selection, the information display 214 may create the graph Gr showing the edge position of the selected edge E1 in color, in the same manner as in FIG. 16.

After the user's selection, the information display 214 may display on the monitor 202 relevant information obtained from the edge information for the selected edge in addition to the graph Gr for the selected edge. The information display 214 may display on the monitor 202 at least one of the first relevant information 252, the second relevant information 254, and various information other than the first relevant information 252 and the second relevant information 254, as the relevant information, along with the graph Gr on the monitor 202.

The contribution rate calculator 222 may calculate contribution rates of the first component, the second component, a third component, a fourth component, and the residual component, respectively, instead of the contribution rates of the first component, the second component, and the residual component. The first relevant information 252 may include information indicating the contribution rates of the first component, the second component, the third component, the fourth component, and the residual component. The contribution rate calculator 222 may perform polynomial model fitting by using an approximate equation described in the following expression (9) instead of the above-described expression (5). As compared to the expression (5), the expression (9) has additional terms of cos 3θ, sin 3θ, cos 4θ, and sin 4θ.

$$[ Formula 3 ]$$

$$w = w 0 + ( - c 1 ) cos θ + ( - s 1 ) sin θ + ( - c 2 ) cos 2 θ + ( - s 2 ) sin 2 θ + ( - c 3 ) cos 3 θ + ( - s 3 ) sin 3 θ + ( - c 4 ) cos 4 θ + ( - s 4 ) sin 4 θ \qquad ( 9 )$$

For example, when calculating the contribution rate of each component, the contribution rate calculator 222 standardizes each cut width included in the edge information so that an average becomes 0 and a standard deviation becomes 1, the same as in the above-described example. For the standardized cut width, the contribution rate calculator 222 calculates the coefficients of the approximate equation shown in the expression (9) by model fitting. After standardizing the cut width and calculating the coefficients of the approximate equation, the contribution rate calculator 222 calculates the contribution rates of the first component, the second component, the third component, the fourth component, and the residual component by using the following expressions (10) to (14).

$$[ Formula 4 ]$$

$$Contribution rate of first component : \qquad ( 10 )$$

$${r}^{2} \frac{\vert c 1 + s 1 \vert}{\vert c 1 + s 1 + c 2 + s 2 + c 3 + s 3 + c 4 + s 4 \vert}$$

$$Contribution rate of second component : \qquad ( 11 )$$

$${r}^{2} \frac{\vert c 2 + s 2 \vert}{\vert c 1 + s 1 + c 2 + s 2 + c 3 + s 3 + c 4 + s 4 \vert}$$

$$Contribution rate of third component : \qquad ( 12 )$$

$${r}^{2} \frac{\vert c 3 + s 3 \vert}{\vert c 1 + s 1 + c 2 + s 2 + c 3 + s 3 + c 4 + s 4 \vert}$$

$$Contribution rate of fourth component : \qquad ( 13 )$$

$${r}^{2} \frac{\vert c 4 + s 4 \vert}{\vert c 1 + s 1 + c 2 + s 2 + c 3 + s 3 + c 4 + s 4 \vert}$$

$$Contribution rate of residual component : 1 - {r}^{2} \qquad ( 14 )$$

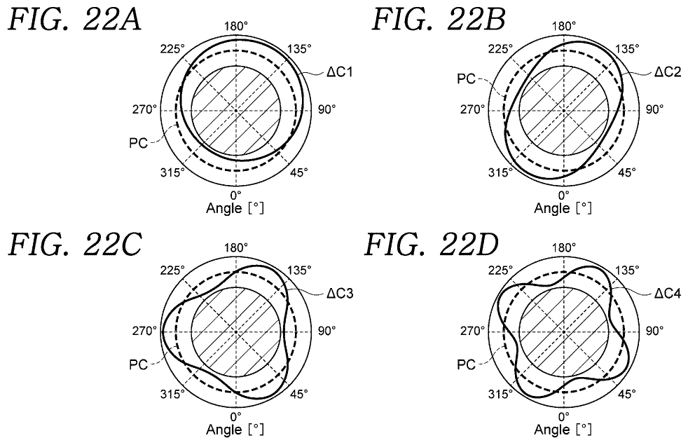

In the example of the first relevant information 252 shown in FIG. 21, “Eccentricity” represents the first component, “Ellipse” represents the second component, “3 cycles” represents the third component, “4 cycles” represents the fourth component, and “Roughness” represents the residual component. In FIG. 22A, a plot group ΔC1 based on the first component (component resulting from eccentricity) is shown, and “PC” denotes a circle. Here, a “plot group” means a set of individual points drawn in a scatter plot. When the plot group ΔC1 is observed one round from a certain reference point of circumferential position (when viewed in a graph of rectangular coordinates), it is transformed to have one peak and one valley. In FIG. 22B, a plot group ΔC2 based on the second component (component resulting from ellipse) is shown. The plot group ΔC2 is transformed to have two peaks and two valleys when observed one round from a certain reference point of circumferential position.

FIG. 22C shows a plot group ΔC3 based on the third component. The plot group ΔC3 is transformed to have three peaks and three valleys when observed one round from a certain reference point of circumferential position. The third component can be said to be non-uniformity resulting from the edge shape's becoming a shape having a three-cycle variation. By using (−c3) and (−s3), an amplitude and a polar angle in the shape having the three-cycle variation can be calculated. FIG. 22D shows a plot group ΔC4 based on the fourth component. The plot group ΔC4 is transformed to have four peaks and four valleys on a graph when observed one round from a reference point of circumferential position. The fourth component can be said to be non-uniformity resulting from the edge shape's becoming a shape having a four-cycle variation. By using (−c4) and (−s4), an amplitude and a polar angle in the shape with the four-cycle variation can be calculated.

The residual component is a component caused by a residual other than the first, second, third, and fourth components (non-uniformity resulting from the residual). As described above, as examples of the polynomial expression for performing the model fitting, the expression (5) including the terms up to cos 2θ and sin 2θ, and the expression (9) including the terms up to cos 4θ and sin 4θ are described. However, the polynomial expression for the model fitting is not limited to the expressions (5) and (9), and may be an expression including the terms up to cos (nθ) and sin (nθ) (n is an integer equal to or greater than 2).

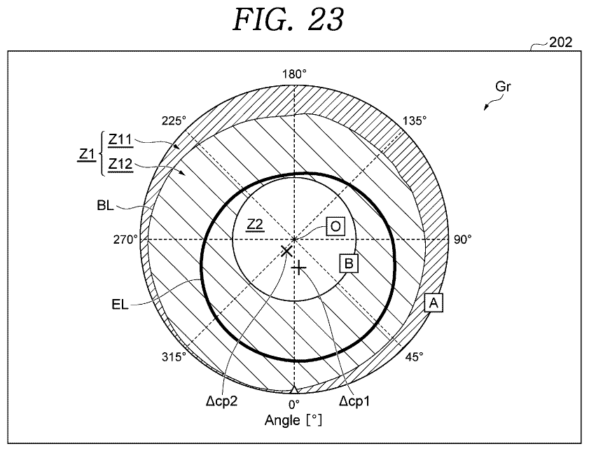

FIG. 23 illustrates an example where the graph Gr is displayed on the monitor 202 in a manner different from the various examples described above. When the bevel portion BP exists at the outer periphery of the wafer W, the captured peripheral image PI may be obtained by performing the imaging so as to include the boundary bL between the bevel portion BP and the portion other than the bevel portion BP. The information acquirer 212 may acquire boundary information from the captured peripheral image PI in the same way as in the acquisition of the edge information for the edge of the resist film R1. The boundary information is information indicating, for each circumferential position, a relationship between the circumferential position and a position of the boundary bL in the radial direction of the wafer W (hereinafter referred to as “boundary position of the bevel portion BP”). The boundary position of the bevel portion BP may be defined as the shortest distance between a theoretical position of the outer end of the wafer W and the boundary bL in the radial direction.

The information display 214 may display the graph Gr on the monitor 202 so that the boundary position of the bevel portion BP for each circumferential position is indicated in the graph Gr in addition to the edge position for each circumferential position. In FIG. 23, a plot group (a set of points) indicated by “EL” represents the edge position for each circumferential position.

As one example, the information display 214 displays the display area Z1, which represents an area in which the plot group EL for the edge position is drawn, while dividing it into two areas according to the boundary position of the bevel portion BP. In FIG. 23, among the areas divided by the boundary position of the bevel portion BP, an area located on the outer side is denoted by “Z11”, and the area located on the inner side is denoted by “Z12”. The information display 214 may display (draw) the areas Z11 and Z12 in different ways. As an example, the areas Z11 and Z12 may have different color density in grayscale, different colors, or different background patterns. In this case, the boundary bL between the areas Z11 and Z12 on the graph Gr indicates the boundary position of the bevel portion BP for each circumferential position.

Instead of displaying the two areas in different ways, the information display 214 may display the background of the entire display area Z1 in a uniform manner, and then draw a group of plots (a set of points) indicating the boundary position of the bevel portion BP on the graph Gr in the same manner as in the case of drawing the plot group EL. The information display 214 may display, on the graph Gr, a center Δcp1 of an edge shape based on the information on the edge of the resist film R1, and a center Δcp2 of a shape based on the information on the boundary position of the bevel portion BP.

By simultaneously displaying the information on the edge of the resist film R1 and the information on the boundary position of the bevel portion BP on the graph Gr, the operator or the like can easily grasp a relationship between the shape of the boundary bL and the edge shape. The shape of the boundary bL means an outer end of the front surface Wa of the wafer W within an available range. For example, if the position of the boundary bL in the radial direction of the wafer W differs depending on the circumferential position, even if the position of the nozzle 71 configured to discharge the processing liquid L2 for removing a part of the resist film R is same, a state of the flow of the processing liquid L2 changes after the processing liquid L2 is discharged. Due to this change, the edge position (cut width) of the resist film R1 may vary depending on the circumferential position. As one example, if the shape of the boundary position of the bevel portion BP and the edge shape of the resist film R1 show the same tendency on the graph Gr, the operator or the like may make a determination that the shape of the wafer W itself before being subjected to formation of the resist film is highly likely to be a cause of abnormality such as eccentricity.

In the above-described exemplary embodiment, the resist film R is formed by applying the processing liquid L1. However, the way to form the resist film R is not limited thereto. The patterning film forming apparatus included in the wafer processing system 1 may form the resist film R by vapor deposition (for example, CVD: Chemical Vapor Deposition). Also, the patterning film forming apparatus may form the resist film R by any of various methods other than the coating of the processing liquid L1 and the vapor deposition.

In the above-described exemplary embodiment, the peripheral portion of the resist film R is removed by the processing liquid L2. However, the way to remove the peripheral portion is not limited thereto. The peripheral portion of the resist film R may be removed by a periphery exposure apparatus provided in the wafer processing system 1. Also, the wafer processing system 1 may remove the peripheral portion of the resist film R by any of various methods other than the supply of the processing liquid L2 and the exposure.

The resist film R of a ring shape may be formed on the peripheral region of the front surface Wa of the wafer W. In this case, the information acquirer 212 of the display device 200 may acquire a position of an inner end of the ring-shaped resist film R for each of multiple circumferential positions as edge information. The film whose edge information is to be displayed by the display device 200 is not limited to the resist film R. The display device 200 may display the graph Gr showing an edge position of any of various types of films on the monitor 202. In one of the above-described various examples, at least some of the matters described in the other examples may be combined.

### Summary of Present Disclosure

The present disclosure includes the following methods or components (1) to (21).

(1) A display method, including: acquiring, based on an image PI obtained by imaging a peripheral region of a front surface Wa of a substrate W having a film R1 formed on the front surface Wa thereof, edge information indicating a relationship between a circumferential position and an edge position of the film R1 in a radial direction of the substrate W for each of multiple circumferential positions around a center of the substrate W; displaying, on a monitor 202, a graph Gr indicating the edge position for each of the multiple circumferential positions based on the edge information; and determining, before displaying the graph Gr on the monitor 202, a display range for the edge position on the graph Gr based on statistical information of the edge position included in the edge information.

In this display method, the display range for the edge position on the graph Gr is determined based on the statistical information of the edge position included in the edge information. Depending on the setting of the display range, there may arise occasions where an edge shape, which is obtained from the edge information, is difficult to evaluate, such as when a tendency in a change in the edge position is not observable, or some data of the edge position is not displayed. In contrast, in the above-described display method, since the display range is determined based on the statistical information, an operator or the like who has observed the graph Gr can draw the graph Gr on the monitor 202 in a range where it is easy to evaluate the edge shape obtained from the edge information. Therefore, the above-described display method enables easy evaluation of the edge shape of the film.

(2) The display method described in (1), wherein the statistical information includes at least some of five-number summary obtained when creating a box-and-whisker diagram for the edge position from the edge information.

In this case, the display range on the graph Gr varies according to the information for creating the box-and-whisker diagram. Therefore, it is possible for the operator or the like to easily evaluate an edge state in the edge shape by looking at the graph Gr.

(3) The display method described in (2), wherein, in the determining of the display range, the display range is determined based on a median or an average value of the edge position included in the edge information and a value obtained by multiplying a difference between a third quartile and a first quartile by a constant greater than 1.

In this case, it is easy for the operator or the like to identify a change in the edge position due to a change in the circumferential position, while suppressing necessary data in the edge information from not being displayed.

(4) The display method described in any one of (1) to (3), wherein the graph Gr is a graph of polar coordinates in which a distance from an origin represents the edge position and an angle around the origin represents the circumferential position.

In this case, the edge state based on the edge information can be displayed to the operator or the like in a format close to an actual edge shape. Therefore, it becomes possible to evaluate the edge shape of the film more easily.

(5) The display method described in (4), wherein, in the displaying of the graph Gr on the monitor 202, points respectively corresponding to the multiple circumferential positions to indicate the edge position are displayed in colors corresponding to a size of the edge position.

In this case, the size of the edge position with respect to a reference position (for example, an outer end position of a surface) can be grasped even based on a difference in color. Therefore, it is possible to improve the convenience of a user such as the operator.

(6) The display method described in any one of (1) to (3), wherein the graph Gr is a graph of rectangular coordinates in which a vertical axis represents the edge position, and a horizontal axis represents the circumferential position.

In this case, since a change in the edge position appears as a change on the vertical axis, it is easy for the operator or the like to understand the change in the edge position.

(7) The display method described in any one of (1) to (6), further including: in non-uniformity of the edge position in the edge information, displaying, on the monitor 202, at least, a contribution rate of a first component resulting from eccentricity, which indicates a difference between a center of an edge shape obtained by the edge position at each of the multiple circumferential positions and the center of the substrate W; a contribution rate of a second component resulting from that the edge shape is an ellipse; and a contribution rate of a residual component resulting from a residual.

In this case, the operator or the like can easily find out which factor has caused the non-uniformity of the edge position and to what extent that factor has contributed.

(8) The display method described in any one of (1) to (7), further including: identifying a type of abnormality that exists between an edge shape obtained by the edge position at each of the multiple circumferential positions and a theoretical edge shape; determining, based on information in which the type of the abnormality is matched with a candidate for countermeasure to resolve the abnormality, a candidate for countermeasure according to an identification result of the type of the abnormality; and displaying, on the monitor 202, the identification result of the type of the abnormality and a determination result of the candidate for countermeasure.

In this case, even an inexperienced operator or the like can easily come up with a high-priority countermeasure to be taken next. As a result, it is unlikely that a difference will arise between operators and other individuals in the implementation of countermeasures to resolve the abnormality.

(9) The display method described in (8), wherein the graph Gr, the identification result of the type of the abnormality, the determination result of the candidate for countermeasure, and a contribution rate for non-uniformity of the edge position in the edge information are displayed together on the monitor 202, and the contribution rate includes: a contribution rate of a first component resulting from eccentricity, which indicates a difference between a center of an edge shape obtained by the edge position at each of the multiple circumferential positions and the center of the substrate W; a contribution rate of a second component resulting from that the edge shape is an ellipse; and a contribution rate of a residual component resulting from a residual.

In this case, the operator or the like can take the various information into account comprehensively and make an appropriate decision on a countermeasure.

(10) The display method described in any one of (1) to (9), wherein the image PI is obtained by performing the imaging so as to include a boundary bL between a bevel portion BP formed at an outer periphery of the substrate W and a portion other than the bevel portion BP, and the graph Gr displayed on the monitor 202 shows, in addition to the edge position for each circumferential position, a position of the boundary bL in the radial direction of the substrate W for each circumferential position.

In this case, the operator or the like can easily understand a relationship between the shape of the boundary bL and the edge shape from the graph Gr.

(11) A computer-readable recording medium having stored thereon computer-executable instructions that, in response to execution, cause an apparatus to perform a display method as described in any one of (1) to (10).

(12) A display device 200, including: an information acquirer 212 configured to acquire, based on an image PI obtained by imaging a peripheral region of a front surface Wa of a substrate W having a film R1 formed on the front surface Wa thereof, edge information indicating a relationship between a circumferential position and an edge position of the film R1 in a radial direction of the substrate W for each of multiple circumferential positions around a center of the substrate W; an information display 214 configured to display, on a monitor 202, a graph Gr indicating the edge position for each of the multiple circumferential positions based on the edge information; and a range determiner 216 configured to determine, before displaying the graph Gr on the monitor 202, a display range for the edge position on the graph Gr based on statistical information of the edge position included in the edge information.

This display device, like the display method as describe above, makes it possible to easily evaluate an edge shape of the film.

(13) The display device 200 described in (12), wherein the statistical information includes at least some of five-number summary obtained when creating a box-and-whisker diagram for the edge position from the edge information.

In this case, it is possible for the operator or the like to easily evaluate an edge state in the edge shape by looking at the graph Gr.

(14) The display device 200 described in (13), wherein the range determiner 216 determines the display range based on a median or an average value of the edge position included in the edge information and a value obtained by multiplying a difference between a third quartile and a first quartile by a constant greater than 1.

In this case, it is easy for the operator or the like to identify a change in the edge position due to a change in the circumferential position, while suppressing necessary data in the edge information from not being displayed.

(15) The display device 200 described in any one of (12) to (14), wherein the graph Gr is a graph of polar coordinates in which a distance from an origin O represents the edge position and an angle around the origin O represents the circumferential position.

In this case, the edge state based on the edge information can be displayed to the operator or the like in a format close to an actual edge shape. Therefore, it becomes possible to evaluate the edge shape of the film more easily.

(16) The display device 200 described in (15), wherein when displaying the graph Gr on the monitor 202, the information display 214 displays points respectively corresponding to the multiple circumferential positions to indicate the edge position in colors corresponding to a size of the edge position.

In this case, the size of the edge position with respect to a reference position (for example, an outer end position of a surface) can be grasped even based on a difference in color. Therefore, it is possible to improve the convenience of a user such as the operator.

(17) The display device 200 described in any one of (12) to (14), wherein the graph Gr is a graph of rectangular coordinates in which a vertical axis represents the edge position, and a horizontal axis represents the circumferential position.

In this case, since a change in the edge position appears as a change on the vertical axis, it is easy for the operator or the like to understand the change in the edge position.

(18) The display device 200 described in any one of (12) to (17), wherein, in non-uniformity of the edge position in the edge information, the information display 214 displays, on the monitor 202, at least, a contribution rate of a first component resulting from eccentricity, which indicates a difference between a center of an edge shape obtained by the edge position at each of the multiple circumferential positions and the center of the substrate W; a contribution rate of a second component resulting from that the edge shape is an ellipse; and a contribution rate of a residual component resulting from a residual.

In this case, the operator or the like can easily find out which factor has caused the non-uniformity of the edge position and to what extent that factor has contributed.

(19) The display device 200 described in any one of (12) to (17), further including: abnormality identifier 224 configured to identify a type of abnormality that exists between an edge shape obtained by the edge position at each of the multiple circumferential positions and a theoretical edge shape; and a countermeasure candidate determiner 226 configured to determine, based on information in which the type of the abnormality is matched with a candidate for countermeasure to resolve the abnormality, a candidate for countermeasure according to an identification result of the type of the abnormality, wherein the information display 214, on the monitor 202, displays the identification result of the type of the abnormality and a determination result of the candidate for countermeasure.

In this case, even an inexperienced operator or the like can easily come up with a high-priority countermeasure to be taken next. As a result, it is unlikely that a difference will arise between operators and other individuals in the implementation of countermeasures to resolve the abnormality.

(20) The display device 200 described in (19), wherein the information display 214 displays, on the monitor 202, the graph Gr, the identification result of the type of the abnormality, the determination result of the candidate for countermeasure, and a contribution rate for non-uniformity of the edge position in the edge information, and the contribution rate includes: a contribution rate of a first component resulting from eccentricity, which indicates a difference between a center of an edge shape obtained by the edge position at each of the multiple circumferential positions and the center of the substrate W; a contribution rate of a second component resulting from that the edge shape is an ellipse; and a contribution rate of a residual component resulting from a residual.

In this case, the operator or the like can take the various information into account comprehensively and make an appropriate decision on a countermeasure.

(21) The display device 200 described in any one of (12) to (20), wherein the image PI is obtained by performing the imaging so as to include a boundary bL between a bevel portion BP formed at an outer periphery of the substrate W and a portion other than the bevel portion BP, and the information display 214 displays, on the monitor 202, the graph Gr that shows, in addition to the edge position for each circumferential position, a position of the boundary bL in the radial direction of the substrate W for each circumferential position.

In this case, the operator or the like can easily understand a relationship between the shape of the boundary bL and the edge shape from the graph Gr.

According to the exemplary embodiment, it is possible to provide the display device, the recording medium, and the display method enabling easy evaluation of the edge shape of the film.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A display method, comprising:
acquiring, based on an image obtained by imaging a peripheral region of a front surface of a substrate having a film formed on the front surface thereof, edge information indicating a relationship between a circumferential position and an edge position of the film in a radial direction of the substrate for each of multiple circumferential positions around a center of the substrate;
displaying, on a monitor, a graph indicating the edge position for each of the multiple circumferential positions based on the edge information; and
determining, before displaying the graph on the monitor, a display range for the edge position on the graph based on statistical information of the edge position included in the edge information.

2. The display method of claim 1,
wherein the statistical information includes at least some of five-number summary obtained when creating a box-and-whisker diagram for the edge position from the edge information.

3. The display method of claim 2,
wherein, in the determining of the display range, the display range is determined based on a median or an average value of the edge position included in the edge information and a value obtained by multiplying a difference between a third quartile and a first quartile by a constant greater than 1.

4. The display method of claim 1,
wherein the graph is a graph of polar coordinates in which a distance from an origin represents the edge position and an angle around the origin represents the circumferential position.

5. The display method of claim 4,
wherein, in the displaying of the graph on the monitor, points respectively corresponding to the multiple circumferential positions to indicate the edge position are displayed in colors corresponding to a size of the edge position.

6. The display method of claim 1,
wherein the graph is a graph of rectangular coordinates in which a vertical axis represents the edge position, and a horizontal axis represents the circumferential position.

7. The display method of claim 1, further comprising:
in non-uniformity of the edge position in the edge information, displaying, on the monitor, at least,
a contribution rate of a first component resulting from eccentricity, which indicates a difference between a center of an edge shape obtained by the edge position at each of the multiple circumferential positions and the center of the substrate;
a contribution rate of a second component resulting from that the edge shape is an ellipse; and
a contribution rate of a residual component resulting from a residual.

8. The display method of claim 1, further comprising:
identifying a type of abnormality that exists between an edge shape obtained by the edge position at each of the multiple circumferential positions and a theoretical edge shape;
determining, based on information in which the type of the abnormality is matched with a candidate for countermeasure to resolve the abnormality, a candidate for countermeasure according to an identification result of the type of the abnormality; and
displaying, on the monitor, the identification result of the type of the abnormality and a determination result of the candidate for countermeasure.

9. The display method of claim 8,
wherein the graph, the identification result of the type of the abnormality, the determination result of the candidate for countermeasure, and a contribution rate for non-uniformity of the edge position in the edge information are displayed together on the monitor, and
the contribution rate includes:
a contribution rate of a first component resulting from eccentricity, which indicates a difference between a center of an edge shape obtained by the edge position at each of the multiple circumferential positions and the center of the substrate;
a contribution rate of a second component resulting from that the edge shape is an ellipse; and
a contribution rate of a residual component resulting from a residual.

10. The display method of claim 1,
wherein the image is obtained by performing the imaging so as to include a boundary between a bevel portion formed at an outer periphery of the substrate and a portion other than the bevel portion, and
the graph displayed on the monitor shows, in addition to the edge position for each circumferential position, a position of the boundary in the radial direction of the substrate for each circumferential position.

11. A computer-readable recording medium having stored thereon computer-executable instructions that, in response to execution, cause an apparatus to perform a display method as claimed in claim 1.

12. A display device, comprising:
an information acquirer configured to acquire, based on an image obtained by imaging a peripheral region of a front surface of a substrate having a film formed on the front surface thereof, edge information indicating a relationship between a circumferential position and an edge position of the film in a radial direction of the substrate for each of multiple circumferential positions around a center of the substrate;
an information display configured to display, on a monitor, a graph indicating the edge position for each of the multiple circumferential positions based on the edge information; and
a range determiner configured to determine, before displaying the graph on the monitor, a display range for the edge position on the graph based on statistical information of the edge position included in the edge information.

13. The display device of claim 12,
wherein the statistical information includes at least some of five-number summary obtained when creating a box-and-whisker diagram for the edge position from the edge information.

14. The display device of claim 13,
wherein the range determiner determines the display range based on a median or an average value of the edge position included in the edge information and a value obtained by multiplying a difference between a third quartile and a first quartile by a constant greater than 1.

15. The display device of claim 12,
wherein the graph is a graph of polar coordinates in which a distance from an origin represents the edge position and an angle around the origin represents the circumferential position.

16. The display device of claim 15,
wherein when displaying the graph on the monitor, the information display displays points respectively corresponding to the multiple circumferential positions to indicate the edge position in colors corresponding to a size of the edge position.

17. The display device of claim 12,
wherein the graph is a graph of rectangular coordinates in which a vertical axis represents the edge position, and a horizontal axis represents the circumferential position.

18. The display device of claim 12,
wherein, in non-uniformity of the edge position in the edge information, the information display displays, on the monitor, at least,
a contribution rate of a first component resulting from eccentricity, which indicates a difference between a center of an edge shape obtained by the edge position at each of the multiple circumferential positions and the center of the substrate;
a contribution rate of a second component resulting from that the edge shape is an ellipse; and
a contribution rate of a residual component resulting from a residual.

19. The display device of claim 12, further comprising:
abnormality identifier configured to identify a type of abnormality that exists between an edge shape obtained by the edge position at each of the multiple circumferential positions and a theoretical edge shape; and
a countermeasure candidate determiner configured to determine, based on information in which the type of the abnormality is matched with a candidate for countermeasure to resolve the abnormality, a candidate for countermeasure according to an identification result of the type of the abnormality,
wherein the information display, on the monitor, displays the identification result of the type of the abnormality and a determination result of the candidate for countermeasure.

20. The display device of claim 19,
wherein the information display displays, on the monitor, the graph, the identification result of the type of the abnormality, the determination result of the candidate for countermeasure, and a contribution rate for non-uniformity of the edge position in the edge information, and
the contribution rate includes:
a contribution rate of a first component resulting from eccentricity, which indicates a difference between a center of an edge shape obtained by the edge position at each of the multiple circumferential positions and the center of the substrate;
a contribution rate of a second component resulting from that the edge shape is an ellipse; and
a contribution rate of a residual component resulting from a residual.
